(19) United States
(12) Patent Application Publication
(10) Pub. No.: US 2004/0238820 A1
(43) Pub. Date: Dec. 2, 2004

(54) Semiconductor device and a method of manufacturing the same

(75) Inventors: Mitsunori Sakama, Kanagawa (JP); Taketomi Asami, Kanagawa (JP); Noriko Ishimaru, Kanagawa (JP); Shunpei Yamazaki, Tokyo (JP)

Correspondence Address: Edward D. Manzo, Cook, Alex, McFarron, Manzo,, Cummings & Mehler, Ltd., 200 West Adams St., Ste. 2850, Chicago, IL, 60606, US

(73) Assignee: Semiconductor Energy Laboratory Co., Ltd.

(21) Appl. No.: 10/669,284

(22) Filed: Sep. 24, 2003

Related U.S. Application Data
(62) Division of application No. 09/584,617, filed on May 31, 2000, now abandoned.

(30) Foreign Application Priority Data
Jun. 2, 1999 (JP) 11-154429

(51) Int. Cl. H01L 21/84; H01L 31/036

(52) U.S. Cl. 257/59; 257/72; 438/149

(57) ABSTRACT

An objective is to provide an insulating film suitable for a semiconductor device, typically a TFT, and a method of manufacturing the insulating film. A semiconductor device using this type of insulating film for a gate insulating film, a base film, and a protective insulating film or an interlayer insulating film, and a method of its manufacture, are provided. The insulating film is manufactured from a hydrogenated silicon oxynitride film by plasma CVD using SiH₄, N₂O, and H₂ as raw material gasses. It has a composition in which the oxygen concentration is set from 55 to 70 atomic %, the nitrogen concentration is set from 0.1 to 6 atomic %, preferably between 0.1 and 2 atomic %, and the hydrogen concentration is set from 0.1 to 3 atomic %. In order to make a film with this composition, the substrate temperature is set from 350 to 500° C., preferably between 400 and 450° C., and the electric discharge power density is set between 0.1 and 1 W/cm².

### BACKGROUND OF THE INVENTION

1. Field of the Invention

The present invention relates to a thin film transistor and a method of manufacturing the same, specifically to an insulating film material necessary for forming the thin film transistor and a method of manufacturing the transistor.

2. Description of the Related Art

There has been developed a thin-film transistor (hereafter referred to as a TFT), having an active layer made from a crystalline semiconductor film, which is crystallized by a method such as laser annealing or thermal annealing from an amorphous semiconductor film, formed on an insulating substrate having light transparency characteristics, such as a glass. The substrate mainly used in the manufacture of the TFT is a glass substrate such as a barium borosilicate glass or alumino borosilicate glass. This type of glass substrate has inferior resistance to heat when compared with a quartz substrate, but has the advantages of a low market price, and the fact that a large surface area substrate can be easily manufactured.

The structure of the TFT can be roughly divided into a top gate type and a bottom gate type, with respect to the arrangement of a gate electrode. In the top gate type, an active layer is formed on an insulating substrate such as a glass substrate, and a gate insulating film and a gate electrode are formed in order on the active layer. Furthermore, there are many cases in which a base film is formed between the substrate and the active layer. On the other hand, a gate electrode is formed on a similar substrate in the bottom gate type, and a gate insulating film and an active layer are formed in order on the gate electrode. In addition, a protective insulating film or an interlayer insulating film is formed on the active layer.

The gate insulating film, the base film, and the protective insulating film or the interlayer insulating film are manufactured from a film such as a silicon oxide film, a silicon nitride film, or a silicon oxynitride film. The reason that these types of materials are used is because in order to form a good interface with respect to an amorphous silicon film or a crystalline silicon film forming the active layer, it is preferable to form the insulating films from a material having silicon as one of the principal constituents.

It is considered as preferable to manufacture the above insulating films by plasma CVD or low pressure CVD. Plasma CVD is a technique of decomposing a raw material gas in a glow discharge, forming a radical (meaning here a chemically activated one) by being made into a plasma, and depositing this on the substrate. In plasma CVD, it is possible to deposit a film at high speed at a low temperature of normally 400° C. or less. However, ions also exist within the plasma, and therefore it is necessary to skillfully control the damage to the substrate due to ions accelerated by an electric field occurring in a sheath region. On the other hand, low pressure CVD is a method of thermally decomposing a raw material gas and depositing a film on the substrate. There is no damage to the substrate due to ions, as with plasma CVD, but low pressure CVD has the disadvantage of slow deposition speed.

Whichever is used, it is necessary to sufficiently reduce the interface level density and the defect level density within the film (bulk defect density) in order to make the film into the gate insulating film, the base film, or the protective insulating film or the interlayer insulating film of the TFT. In addition, it is necessary to consider the amount of change due to internal stress or due to heat treatment.

In order to form a good quality insulating film, it is essential not to introduce any defects in the film deposition process, and to use a composition which reduces the defect level density of the formed film. A means of using a raw material gas having a high decomposition ratio has been considered for that reason. For example, manufacturing a silicon oxide film by plasma CVD using a gas mixture of TEOS (tetraethyl orthosilicate, chemical formula Si(OC₂H₅)₄) and oxygen (O₂) is one of the methods which can form a good quality insulating film. If this silicon oxide film is used to manufacture a MOS structure and then BTS (bias, thermal, stress) testing is performed, it is known that the change in flat band voltage (hereafter referred to as V_{fb}) can be reduced to a practical use range.

However, water (H₂O) is easily created in a process of glow discharge decomposition of TEOS, and this easily is taken into the film. Therefore it is necessary to perform thermal annealing at between 400 and 600° C. after film deposition in order to make a good quality film as stated above. The incorporation of this type of high temperature annealing step into the TFT manufacturing process is unsuitable because it is a cause of an increase in manufacturing cost.

On the other hand, a silicon oxynitride film formed by plasma CVD using a gas mixture of SiH₄ and N₂O is densified by the several atomic % of nitrogen contained within the film, and a good quality film can be manufactured without the need to perform thermal annealing. However, depending upon the manufacturing conditions, defect levels are formed by Si—N bonding, which causes, in some cases, increased amount of change in V_{fb} and shifts occurring in the threshold voltage (hereafter referred to as Vₜₕ) that is one of the TFT characteristics. Similarly, manufacturing a silicon nitride film from gasses such as SiH₄, NH₃, and N₂ using plasma CVD can provide a dense, hard film, but the defect level density is large. Further, the internal stress is large, and therefore if an active layer is formed in direct contact, then distortion is imparted, resulting in a bad influence to the TFT characteristics in which Vₜₕ shifts and in which the sub-threshold coefficient (hereafter referred to as S-value) is made larger.

### SUMMARY OF THE INVENTION

The present invention is a technique for solving the above problems, and an object of the present invention is therefore to provide an insulating film suitable for a semiconductor device, typically a TFT, and a method of manufacturing the same. Furthermore, an object of the present invention is to provide a semiconductor device using this type of insulating film for a gate insulating film, a base film, and a protective insulating film or an interlayer insulating film, and a method of manufacturing the semiconductor device.

In order to solve the above problems, the present invention uses a hydrogenated silicon oxynitride film manufactured by plasma CVD using SiH₄, N₂O, and H₂ as raw material gasses as an insulating film material of a semiconductor device, typically a TFT. By using this type of hydrogenated silicon oxynitride film for the gate insulating film, the base film, and the protective insulating film or the interlayer insulating film, a TFT having no shift in Vₜₕ and which is stable with respect to BTS, can be manufactured.

Reports related to a hydrogenated silicon oxynitride film manufactured by plasma CVD using SiH₄, N₂O, and H₂ as raw material gasses, for example, Yeh, Jiun-Lin, and Lee, Si-Chen, “Structural and Optical Properties of Amorphous Silicon Oxynitride”, Journal of Applied Physics, vol. 79, no. 2, pp. 656-663, 1966, discuss a hydrogenated silicon oxynitride film manufactured by plasma CVD with a decomposition temperature of 250° C., and a mixture ratio of hydrogen (H₂) vs. SiH₄+N₂O fixed at 0.9 to 1.0, in which the value of the mixture ratio Xg, expressed as Xg=[N₂O]/([SiH₄]+[N₂O]), is changed from 0.05 to 0.975. However, the existence of HSi—O₃ bonds and H₂Si—O₂ bonds in the manufactured hydrogenated silicon oxynitride film is clearly observed by Fourier transform infrared spectroscopy (FT-IR). These kinds of bonds will completely degrade the thermal stability and, moreover, there is a fear that the change in the coordination number will form defect level densities in the periphery of the bonds. Therefore, even with the same hydrogenated silicon oxynitride film, if the composition, or components including impurity element, is not examined in detail, then it cannot carelessly be used for as an insulating film such as the gate insulating film which imparts critical influence to the TFT characteristics.

Therefore, the insulating film material of the present invention, i.e., a hydrogenated silicon oxynitride film, is a film manufactured by plasma CVD with SiH₄, N₂O, and H as raw material gasses. It has a composition in which the oxygen concentration is set from 55 to 70 atomic %, the nitrogen concentration is set from 0.1 to 6 atomic %, preferably from 0.1 to 2 atomic %, and the hydrogen concentration is set from 0.1 to 3 atomic %. In order to make a film with this composition, the substrate temperature is set from 350 to 500° C., preferably between 400 and 450° C., and the electric discharge power density is set between 0.1 and 1 W/cm².

By adding hydrogen to the conventionally used SiH₄ and N₂O gas mixture when manufacturing the hydrogenated silicon oxynitride film by plasma CVD, radicals created from the decomposition of SiH₄ is prevented from being polymerized in the gas phase (within the reaction space), to thereby eliminate the creation of particles. Further, in the film growth surface, excess hydrogen can be prevented from being taken into the film by an abstraction reaction of surface adsorbed hydrogen by hydrogen radicals. This kind of action has a close correlation with the substrate temperature during film deposition, and cannot be obtained unless the substrate temperature is set to the range of the present invention. As a result, it is possible to form a dense film with a small defect density, and the trace amount of hydrogen contained within the film works effectively in relieving lattice warping. In order to decompose the water and increase the concentration of hydrogen radicals developed, it is appropriate to set the frequency of the high frequency power supply for generating the glow discharge to between 13.56 and 120 MHz, preferably from 27 to 70 MHz.

In this way, the present invention is to effectively utilize the effect obtained by setting the amounts of oxygen, nitrogen, and hydrogen in the hydrogenated silicon oxynitride film to optimal amounts, which cannot be obtained otherwise. Even with hydrogenated silicon oxynitride films formed by the same manufacturing method, the films are formed with differing compositions depending upon the manufacturing conditions and conditions. For example, inclusion of excess hydrogen brings about the result of an increase in the instability of the film, as stated above.

In addition, by forming the gate insulating film, the base film, and the protective insulating film or the interlayer insulating film of the TFT with this type of hydrogenated silicon oxynitride film, and then performing heat treatment at a temperature from 300° C. to 500° C., hydrogen contained in the hydrogenated silicon oxynitride film is emitted. By diffusing the emitted hydrogen into the active layer, hydrogenation of the active layer can be performed effectively. The preferred embodiments of the present invention are described in detail below.

### BRIEF DESCRIPTION OF THE DRAWINGS

In the accompanying drawings:

FIGS. 1A to 1F are cross-sectional views showing a process of manufacturing a TFT;

FIGS. 2A to 2F are cross-sectional views showing the process of manufacturing the TFT;

FIGS. 3A to 3C are diagrams showing the C-V characteristics of MOS structures each using a hydrogenated silicon oxynitride film;

FIG. 4 is a diagram showing the infrared spectroscopic characteristics of the hydrogenated silicon oxynitride film;

FIGS. 5A to 5E are cross-sectional views showing a process of manufacturing a TFT;

FIGS. 6A to 6E are cross-sectional views showing the process of manufacturing the TFT;

FIGS. 7A to 7E are cross-sectional views showing the process of manufacturing the TFT;

FIGS. 8A to 8D are cross-sectional views showing the process of manufacturing the TFT;

FIGS. 9A to 9D are cross-sectional views showing a process of manufacturing a pixel TFT and driver circuit TFTs;

FIGS. 10A to 10D are cross-sectional views showing manufacturing processes for a pixel TFT and driver circuit TFTs;

FIGS. 11A to 11D are cross-sectional views showing the process of manufacturing the pixel TFT and the driver circuit TFTs;

FIGS. 12A to 12C are cross-sectional views showing the process of manufacturing the pixel TFT and the driver circuit TFTs;

FIG. 13 is a cross-sectional view showing a pixel TFT and driver circuit TFTs;

FIGS. 14A to 14C are top views showing a process of manufacturing driver circuit TFTs;

FIGS. 15A to 15C are top views showing a process of manufacturing a pixel TFT;

FIGS. 16A to 16C are cross-sectional views showing a process of manufacturing driver circuit TFTs;

FIGS. 17Aa to 17C are cross-sectional views showing a process of manufacturing a pixel TFT;

FIG. 18 is a top view showing an input/output terminal, wiring, and circuit arrangement of a liquid crystal display device;

FIG. 19 is a cross-sectional view showing the structure of a liquid crystal display device;

FIG. 20 is a perspective view showing the structure of a liquid crystal display device;

FIG. 21 is a top view showing a pixel in a display region;

FIGS. 22A and 22B are structural diagrams showing an active matrix type organic EL display device;

FIGS. 23A to 23F are diagrams showing examples of a semiconductor device;

FIGS. 24A to 24D are diagrams showing examples of a projector;

FIGS. 25A and 25B are a top view and a cross-sectional view, respectively, showing the structure of an EL display device;

FIGS. 26A and 26B are cross-sectional views showing a pixel portion of the EL display device;

FIGS. 27A and 27B are a top view and a circuit diagram, respectively, of the pixel portion of the EL display device; and

FIGS. 28A to 28C are examples of circuit diagrams of another pixel portion of another EL display device.

### DETAILED DESCRIPTION OF THE PREFERRED EMBODIMENTS

A method of manufacturing an insulating film suitable for a semiconductor device, typically a TFT, is explained in this embodiment. A hydrogenated silicon oxynitride film is useful as this type of insulating film, and the hydrogenated silicon oxynitride film of the present invention is a film manufactured by plasma CVD using SiH₄, N₂O, and H₂ as raw material gasses. The capacitance-voltage characteristics (hereafter abbreviated to as C-V characteristics) obtained when a MOS structure test piece is manufactured using the hydrogenated silicon oxynitride film are shown here.

A capacitive coupling type plasma CVD device may be employed here for the manufacture of the hydrogenated silicon oxynitride film. Typical manufacturing conditions are shown in Table 1. Three kinds of conditions are included in Table 1, and the manufacturing conditions relating to the present invention are #1883 and #1884. The conditions #1876 are the manufacturing conditions for a conventional silicon oxynitride film, and are shown for comparison. Film deposition conditions for the hydrogenated silicon oxynitride film, and preprocessing conditions for a process performed prior to the film deposition are included in Table 1. This preprocessing is not essential, but is useful in increasing the reproducibility of the hydrogenated silicon oxynitride film characteristics, and the repeatability of the TFT characteristics for cases in which the hydrogenated silicon oxynitride film is applied to a TFT.

TABLE 1

| Condition No. | | | #1883 | #1884 | #1876 |
|---|---|---|---|---|---|
| Plasma | Gas (sccm) | H₂ | 200 | 200 | 100 |
| cleaning | | O₂ | 0 | 0 | 100 |
| | Pressure (Pa) | | 20 | 20 | 20 |
| | RF power (W/cm²) | | 0.2 | 0.2 | 0.2 |
| | Processing time (min.) | | 2 | 2 | 2 |
| Film | Gas (sccm) | SiH₄ | 5 | 5 | 4 |
| formation | | N₂O | 120 | 120 | 400 |
| | | H₂ | 500 | 125 | 0 |

| | | | |
|---|---|---|---|
| Pressure (Pa) | 20 | 20 | 40 |
| RF power (W/cm²) | 0.4 | 0.4 | 0.4 |
| Substrate temp. (° C.) | 400 | 400 | 400 |

Referring to Table 1, the preprocessing conditions are to introduce hydrogen at 338 Pa·1/sec and generate a plasma at a pressure of 20 Pa and a high frequency power setting of 0.2 W/cm², and then process for 2 minutes. Further, processing may be performed by introducing hydrogen at 169 Pa·1/sec and oxygen at 169 Pa·1/sec, and then similarly generating a plasma with a pressure of 40 Pa. In addition, although not shown in the table, processing may be performed by introducing N₂O and hydrogen, setting the pressure to between 10 and 70 Pa, setting the high frequency power density from 0.1 to 0.5 W/cm², and processing for several minutes. The substrate temperature during such preprocessing may be between 300 and 450° C., preferably 400° C. Effects of the preprocessing include a cleaning action of the substrate surface on which the films will be deposited, and a stabilizing action of the interface characteristics of the hydrogenated silicon oxynitride film deposited later, the stabilizing action being obtained by having the deposition surface adsorb the hydrogen to temporarily inactivate the surface. Further, by introducing oxygen and N₂O at the same time, there are desirable actions such as the topmost surface of the deposition surface, and its close vicinity, being oxidized, reducing the interface level density.

The deposition conditions of the hydrogenated silicon oxynitride film of the present invention are: the introduction of SiH₄ at between 1 and 17 Pa·1/sec, N₂O at from 169 to 506 Pa·1/sec, and hydrogen at between 169 and 1266 Pa·1/sec; a reaction pressure set between 10 and 70 Pa; a high frequency power density set from 0.1 to 1.0 W/cm²; and a substrate temperature of 300 to 450° C., preferably at 400° C. With the conditions of #1883, the hydrogenated silicon oxynitride film is manufactured with: the introduction of SiH₄ 8.44 Pa·1/sec, N₂O at 203 Pa·1/sec, and hydrogen at 844 Pa·1/sec; a reaction pressure set to 20 Pa; a high frequency power density set to 0.4 W/cm²; and a substrate temperature of 400° C. The high frequency power supply frequency can be applied at between 13.56 and 120 MHz, preferably from 27 to 60 MHz, and 60 MHz is used here. Further, the conditions of #1884 are the same as those of #1883, with the flow rate of hydrogen set to 211 Pa·1/sec. The respective gas flow rates are not limited to these absolute values, but rather their flow rate ratios essentially are more significant. If Xh=[H₂]/([SiH₄]+[N₂O]), an appropriate Xh is in a range of 0.1 to 7. Moreover, as stated above, if Xg=[N₂O]/([SiH₄]+[N₂O]), then an appropriate Xg is in the range of 0.90 to 0.996. The #1876 conditions shown in Table 1 are conventional conditions, and are typical manufacturing conditions of a hydrogenated silicon oxynitride film manufactured without the addition of hydrogen.

The characteristics of the hydrogenated silicon oxynitride film thus manufactured were investigated by first manufacturing MOS structure test pieces and investigating its C-V characteristics and the V_{fb} fluctuations by a BTS test. V_{fb} is 0 V in the most desirable C-V characteristics, and the most desirable result for the BTS test is that there is no change in V_{fb}. Deviations from 0 in this value mean there are many defect level densities in the interface and in the insulating film. The test piece was a single crystal silicon substrate (CZ-P type, <100>, resistivity between 3 and 7 Ωcm) on which a 155 nm thick hydrogenated silicon oxynitride film was formed under the conditions shown in Table 1. A 400 nm thick aluminum (Al) electrode was formed by sputtering, and the electrode surface area was set to 78.5 mm². Further, an Al electrode with the same thickness is formed on the reverse surface of the single crystal silicon substrate, and heat treatment is performed in a hydrogen atmosphere at 350° C. for 30 min, performing sintering. In the BTS test, a voltage of −1.7 MV was applied to the electrode on the hydrogenated silicon oxynitride film, and this was allowed to stand for 1 hour at 150° C.

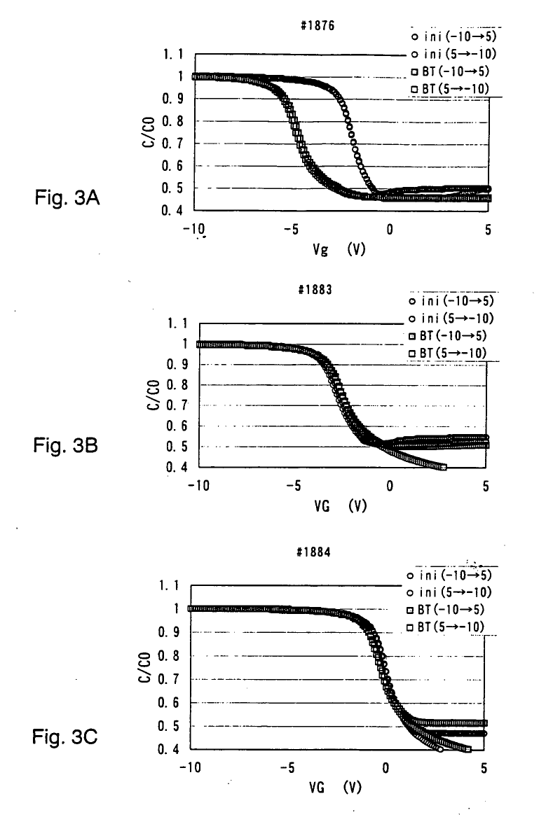

FIGS. 3A to 3C show the C-V characteristics for this type of test pieces. A Yokokawa Hewlett Packard Corp. YHP-4192A was used in making measurements. FIG. 3A shows the characteristics of a hydrogenated silicon oxynitride film manufactured under the #1876 conditions, and there is observed a substantial change in the characteristics before and after the BTS test. On the other hand, FIG. 3B shows the characteristics of a test piece manufactured under the #1883 conditions, and FIG. 3C shows the characteristics of a test piece manufactured under the #1884 conditions. It can be verified in FIGS. 3B and 3C that the change of the characteristics before and after the BTS test is small. Table 2 contains a compilation of V_{fb} values obtained from the C-V characteristics, the initial values and the values after the first BTS test, and the amount of change is shown as ΔV_{fb}. The initial values of V_{fb} were −2.25 V for the test piece under the #1883 conditions, −0.66. V for the test piece under the #1884 conditions, and −2.84 V for the test piece under the #1876 conditions. The ΔV_{fb} values were −0.55 V, −0.15 V, and −1.35 V, respectively. In other words, the test piece manufactured under the #1884 conditions had the smallest initial value of V_{fb} and the smallest value of ΔV_{fb}.

TABLE 2

| Condition No. | | | #1883 | #1884 | #1876 |
|---|---|---|---|---|---|
| C-V data | Vfb(V) | ini | −2.25 | −0.66 | −2.84 |
| | | 1st-BTS | −2.8 | −0.81 | −4.19 |
| | ÄVfb(V) | (-BT)-(ini) | −0.55 | −0.15 | −1.35 |

| | | | |
|---|---|---|---|
| ε′ | 4.017 | 3.796 | 3.569 |

The results of the C-V characteristics suggests that, in the conditions of manufacturing the hydrogenated silicon oxynitride film, there is an optimal range for the proportion of hydrogen mixed in with respect to SiH₄ and N₂O. From the results in FIGS. 3A to 3C, and in Table 2, it has been identified that a good result can be obtained for cases in which Xh=1 and Xg=0.96.

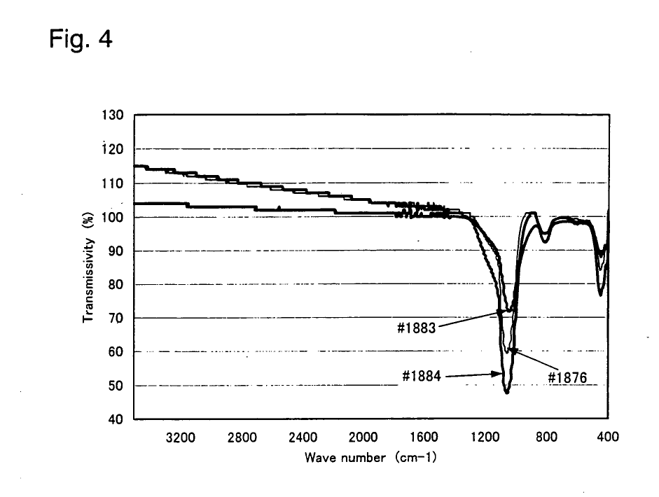

FIG. 4 was prepared from the infrared absorption spectral characteristics of the amount of hydrogen contained in the test pieces, measured by an FT-IR spectroscope (device used: Nicolet Magna-IR 760). The test pieces used for the measurements were deposited on single crystal silicon substrates (FZ-N type, <100>, resistivity of 1000 Ωcm or larger). Stretching mode absorption, having a peak at 1080 to 1050 cm⁻¹, and bending mode absorption, having a peak at 810 cm⁻¹, due to Si—O—Si bonds were observed for all samples. However, the absorption related to Si—H bonding observed in the neighborhood of 2300 to 2000 cm⁻¹, and the absorption related to HSi—O bonding were relatively weakly observed. If the amount of hydrogen contained in the respective test pieces is quantified under the premise that Si—H bonding possesses a stretching mode absorption peak at 2000 cm⁻¹, then this could not be quantified in the test pieces manufactured under the #1876 and #1884 conditions, and it was determined that this bonding had a concentration of 1×10¹⁹ cm⁻³ or less. An Si—H bonding concentration of 4×10¹⁹ cm⁻³ could be quantified for the test piece manufactured under the #1883 conditions. On the other hand, if the N—H bonding concentration obtained by integrating from 3250 to 3400 cm^{31 1} is evaluated, a concentration of 6×10²⁰ cm⁻³ is quantified for the test piece manufactured under the #1883 conditions. A concentration of 4×10²⁰ cm⁻³ is quantified for the test piece manufactured under the #1884 conditions. However, the test piece manufactured under the conventional #1876 conditions could not be quantified.

It was thus confirmed that there is a clear difference in the C-V characteristics among the MOS structure test pieces using hydrogenated silicon oxynitride films that are manufactured in accordance with the three conditions shown in Table 1, and it was confirmed that there are manufacturing conditions under which both the initial value of V_{fb} and its change before and, after BTS testing can be made smaller. It was then also confirmed that there were differences in the concentration of hydrogen contained in the respective films, and from the relation with the C-V characteristics, that there is an optimal composition.

Table 1 and Table 2 show typical examples, but the optimal composition of an insulating film suitable for a semiconductor device, typically a TFT, may be set as follows: an oxygen concentration from 55 to 70 atomic %; a nitrogen concentration from 0.1 to 6 atomic %, preferably from 0.1 to 2 atomic %; and a hydrogen concentration from 0.1 to 3 atomic %.

### Embodiment 1

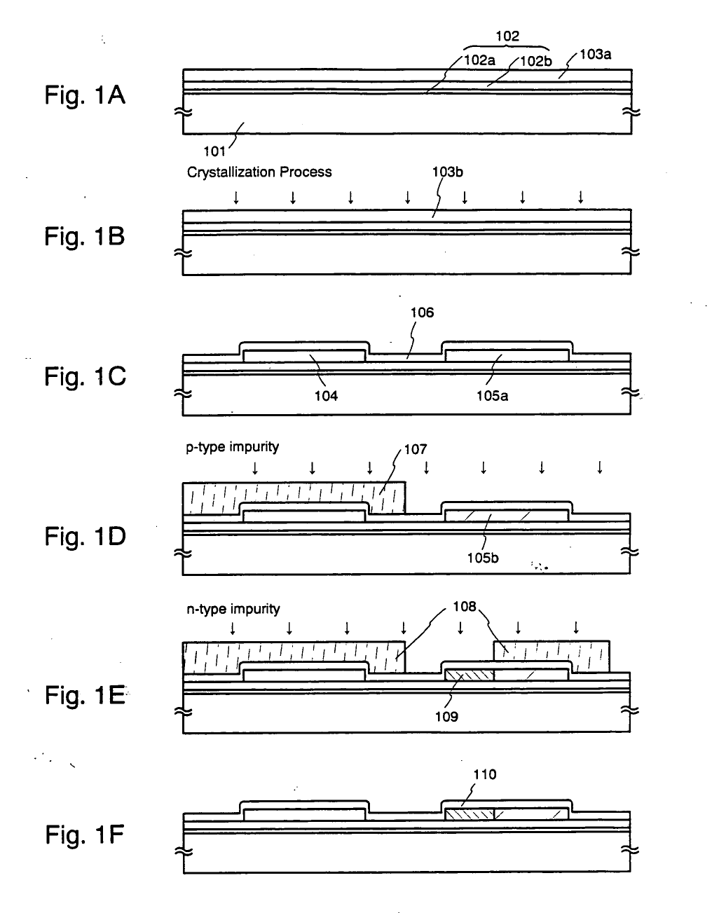

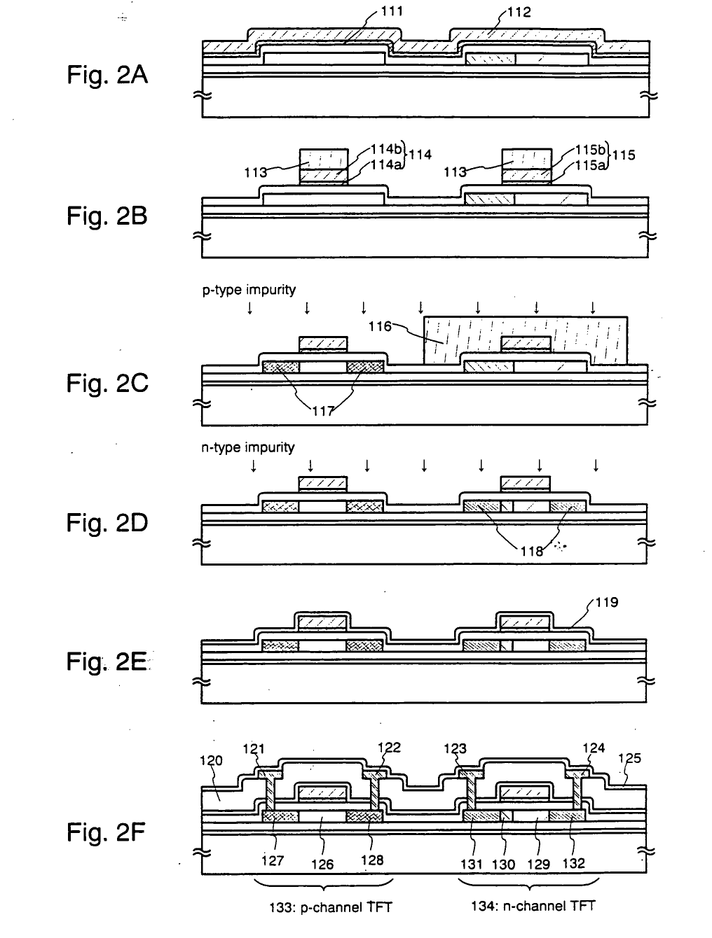

A method of manufacturing an n-channel TFT and a p-channel TFT, necessary for forming a CMOS circuit, on the same substrate is explained in Embodiment 1 in accordance with the process steps using FIGS. 1A to 2F. Insulating films made from the hydrogenated silicon oxynitride film of the present invention are applied to a base film, a gate insulating film, and an interlayer insulating film of the TFTs.

A substrate such as a barium borosilicate glass substrate or alumino borosilicate glass substrate, typically Corning Corp. #7059 glass or #1737 glass substrate, is used for a substrate 101 in FIG. 1A. Alkaline metal elements such as sodium are contained in this type of glass substrate, although at trace amounts. This type of glass substrate shrinks by approximately several ppm to several tens of ppm due to the temperature during heat treatment, and therefore heat treatment may be performed in advance at a temperature on the order of 10 to 20° C. lower than the distortion point of the glass. A base film 102 is formed on the surface of the substrate 101 on which the TFT will be formed, in order to prevent contamination by alkaline metal elements and other impurities from the substrate 101. The base film 102 is formed of a silicon oxynitride film 102a manufactured from SiH₄, NH₃, and N₂O, and of a hydrogenated silicon oxynitride film 102b manufactured from SiH₄, N₂O, and H₂. The silicon oxynitride film 102a is formed with a thickness of 10 to 100 nm (preferably between 20 and 60 nm), and the hydrogenated silicon oxynitride film 102b is formed with a thickness of 10 to 200 nm (preferably between 20 and 100 nm).

These films are formed by using a conventional parallel plate type plasma CVD. To prepare the silicon oxynitride film 102a, SiH₄ is introduced into the reaction chamber at 16.9 Pa·1/sec, NH₃ at 169 Pa·1/sec, and N₂O at 33.8 Pa·1/sec, the substrate temperature is set to 325° C., the reaction pressure to 40 Pa, the electric discharge power density to 0.41 W/cm², and the electric discharge frequency to 60 MHz. On the other hand, to prepare the hydrogenated silicon oxynitride film 102b, SiH₄ is introduced into the reaction chamber at 8.4 Pa·1/sec, N₂O at 203 Pa·1/sec, and H₂ at 211 Pa·1/sec, the substrate temperature is set to 400° C., the reaction pressure to 20 Pa, the electric discharge power density to 0.41 W/cm², and the electric discharge frequency to 60 MHz. These films can be formed in succession by only changing the substrate temperature and changing the reaction gasses.

The silicon oxynitride film 102a formed here has a density of 9.28×10²²/cm³, and it is a dense, hard film with an etching speed at 20° C. in a mixed solution containing 7.13% ammonium hydrogen fluoride (NH₄HF₂) and 15.4% ammonium fluoride (NH₄F) (STELLA CHEMIFA Corp; product name LAL500) which is slow at 63 nm/min. If this type of film is used for the base film, then it is effective in preventing diffusion of alkaline metal elements from the glass substrate into a semiconductor layer formed on the base film.

A semiconductor layer 103a having an amorphous structure is formed next to a thickness of 25 to 80 nm (preferably between 30 and 60 nm) by a known method such as plasma CVD or sputtering. A 55 nm thick amorphous silicon film is formed by plasma CVD in Embodiment 1. Amorphous semiconductor films and microcrystalline semiconductor films exist as semiconductor films having an amorphous structure, and compound semiconductor films having an amorphous structure, such as an amorphous silicon germanium film, may also be applied. Furthermore, both the base film 102 and the amorphous semiconductor layer 103a may be formed in succession. For example, after successively depositing the silicon oxynitride film 102a and the hydrogenated silicon oxynitride film 102b as stated above, if the reaction gasses are changed from SiH₄, N₂O, and H₂ to SiH₄ and H₂, or to SiH₄, then the films can be formed successively without once being exposed to the atmosphere. As a result, it becomes possible to prevent contamination of the surface of the hydrogenated silicon oxynitride film 102b, and fluctuation in the characteristics of the manufactured TFTs, and change in the threshold voltage thereof, can be reduced.

Then crystallization step is carried out in which a crystalline semiconductor layer 103b is formed from the amorphous semiconductor layer 103a. For example, laser annealing and thermal annealing (solid phase growth methods), and rapid thermal annealing (RTA) are applicable. In the RTA method, a lamp such as an infrared lamp, a halogen lamp, a metal halide lamp, or a xenon lamp is used as a light source. Alternatively, the crystalline semiconductor layer 103b can be formed by a crystallization method using a catalytic element, in accordance with the technique disclosed in Japanese Patent Application Laid-open No. Hei 7-130652. It is essential to drive out the hydrogen contained in the amorphous semiconductor layer, and therefore it is desirable to first perform heat treatment for approximately one hour at between 400 and 500° C., reducing the amount of hydrogen contained in the amorphous semiconductor layer to 5 atomic % or less, and then performing crystallization. (FIG. 1B)

When performing crystallization by laser annealing, a pulse oscillation type, or a continuous light emitting type, excimer laser or argon laser is used as the light source. If a pulse oscillation type excimer laser is used, then laser annealing is performed after forming the laser light into a linear shape. The laser annealing conditions may be suitably chosen by the operator, but for example, are set as follows: a laser pulse oscillation frequency of 30 Hz, and a laser energy density of between 100 and 500 mJ/cm² (typically from 300 to 400 mJ/cm²). The linear shape beam is then irradiated over the entire face of the substrate, and irradiation is performed so that the overlap ratio of the linear shape beam is between 80 and 98%. The crystalline semiconductor layer can thus be formed.

For the case of thermal annealing, annealing is performed in a nitrogen atmosphere at a temperature about 600 to 660° C. using an annealing furnace. Whichever method is used, realignment of atoms occurs during crystallization of the amorphous semiconductor layer, making it fine and minute, and the thickness of the crystalline semiconductor layer manufactured is reduced about between 1 and 15% from the thickness of the original amorphous semiconductor layer (55 nm in this embodiment).

A photoresist pattern is then formed on the crystalline semiconductor layer 103b, and the crystalline semiconductor layer is partitioned into island-shapes by dry etching, forming island-like semiconductor layers 104 and 105aas active layers. A mixed gas of CF₄ and O₂ is used in dry etching. A mask layer 106 is then formed from a silicon oxide film with a thickness of 50 to 100 nm formed by plasma CVD, low pressure CVD, or sputtering. For example, if plasma CVD is used, tetraethyl orthosilicate (TEOS) and O₂ are mixed, the reaction pressure is set to 40 Pa, and the substrate temperature is set between 300 and 400° C., and electric discharge is conducted at a high frequency (13.56 MHz) power density of 0.5 to 0.8 W/cm², forming a thickness of 100 to 150 nm, typically 130 nm. (FIG. 1C)

A photoresist mask 107 is then formed, and an impurity element that imparts p-type conductivity is added into the island-like semiconductor layer 105a, which forms the n-channel TFT, at a concentration of 1×10¹⁶ to 5×10¹⁷ atoms/cm³ in order to control the threshold voltage. Periodic table group 13 elements such as boron (B), aluminum (Al), and gallium (Ga) are known as impurity elements which impart p-type conductivity to a semiconductor. Boron (B) is added here by ion doping using diborane (B₂H₆). Boron (B) doping is not always necessary and there is no obstacle in omitting it, but a boron (B) added semiconductor layer 105b can be formed in order to place the threshold voltage of the n-channel TFT within a predetermined range. (FIG. 1D)

In order to form an LDD (lightly doped drain) region of the n-channel TFT, an impurity element that imparts n-type conductivity is selectively added into the island-like semiconductor layer 105b. Periodic table group 15 elements such as phosphorus (P), arsenic (As), and antimony (Sb) are known as impurity elements that impart n-type conductivity to a semiconductor. A photoresist mask 108 is formed, and ion doping using phosphine (PH₃) is applied here for adding phosphorus (P). The concentration of phosphorus (P) in an impurity region 109 formed is in the range of 2×10¹⁶ to 5×10¹⁹ atoms/cm³. The concentration of the impurity element for imparting n-type conductivity contained in the impurity region 109 is referred to as n⁻ throughout this specification. (FIG. 1E)

The mask layer 106 is next removed by using an etching solution such as hydrofluoric acid diluted by pure water. A step of activating the impurity elements added in FIGS. 1D and 1E into the island-like semiconductor layer 105b is then performed. Activation can be performed by a method such as thermal annealing in a nitrogen atmosphere for 1 to 4 hours at between 500 and 600° C., or by laser annealing. Further, both methods may be performed together. A laser activation method using KrF excimer laser light (248 nm wavelength) is performed in this embodiment. The laser light is formed into a linear shape beam, the oscillation frequency is set to between 5 and 50 Hz. and the energy density is set from 100 to 500 mJ/cm². The linear shape beam is scanned with an overlap ratio of between 80 and 98%, processing the entire surface of the substrate on which the island-like semiconductor layers are formed. Note that the irradiation conditions of the laser light are not limited to these conditions, and that the operator may set them appropriately.

Next, a gate insulating film 110, with a thickness of 40 to 150 nm, is formed from an insulating film containing silicon by using plasma CVD. A plasma cleaning process is performed first, before depositing the gate insulating film. The plasma cleaning process is performed for 2 minutes by introducing hydrogen at 338 Pa·1/sec, and then generating a plasma by setting the pressure to 20 Pa and the high frequency power to 0.2 W/cm². Alternatively, hydrogen may be introduced at 169 Pa·1/sec, oxygen at 169 Pa·1/sec, and a plasma may similarly be generated at a pressure of 40 Pa. The substrate temperature is set from 300 to 450° C., preferably at 400° C. By performing the plasma cleaning process on the surfaces of the island-like semiconductor layers 104 and 105b at this stage, contaminating matter such as adsorbed boron or phosphorus, or organic matter, can be removed. Furthermore, by introducing oxygen and N₂O at the same time, the topmost surface of the deposition surface, and its close vicinity, is oxidized, resulting in desirable actions such as a reduction in the interface level density of the interface with the gate insulating film. Formation of the gate insulating film 110 is performed in succession with the plasma cleaning process, and similar to the hydrogenated silicon oxynitride film 102b, stated above, the gate insulating film 110 is formed by introducing SiH₄ into the reaction chamber at 8.4 Pa·1/sec, N₂O at 203 Pa·1/sec, and H₂ at 211 Pa·1/sec, setting the substrate temperature to 400° C., the reaction pressure to 20 Pa, the electric discharge power density to 0.41 W/cm², and the electric discharge frequency to 60 MHz. (FIG. 1F)

A conductive layer is formed on the gate insulating film 110 in order to form a gate electrode. A single layer may be formed for this conductive layer, but a laminate structure of two layers or three layers can also be formed when necessary. In this embodiment, a conductive layer (A) 111 made from a conductive metallic nitride film and a conductive layer (B) 112 made from a metallic film are laminated. The conductive layer (B) 112 may be formed from an element selected from the group consisting of tantalum (Ta), titanium (Ti), molybdenum (Mo), and tungsten (W), or from an alloy having one of these element as its principal constituent, or from an alloy film of a combination of these elements (typically a Mo—W alloy film or a Mo—Ta alloy film). The conductive layer (A) 111 is formed from tantalum nitride (TaN), tungsten nitride (WN), titanium nitride (TiN), or molybdenum nitride (MoN). Further, tungsten silicide, titanium silicide, or molybdenum silicide may be applied for the conductive layer (A) 111. The concentration of contained impurities may be reduced in order to be able to make the resistance of the conductive layer (B) 112 lower, and in particular, it is good to reduce the oxygen concentration to 30 ppm or less. For example, by reducing the oxygen concentration of tungsten (w) to 30 ppm or less, a resistivity value of 20 μΩcm or less can be realized with tungsten (W). (FIG. 2A)

The conductive layer (A) 111 may be from 10 to 50 nm (preferably 20 to 30 nm) in thickness, and the conductive layer (B) 112 may be from 200 to 400 nm (preferably 250 to 350 nm) in thickness. In this embodiment, a TaN film of 30 nm thickness is used for the conductive layer (A) 111, and Ta film of 350 nm thickness is used for the conductive layer (B) 112, and both are formed by sputtering. The TaN film is formed using Ta as a target and a mixed gas of Ar and nitrogen as a sputtering gas. Ta is formed using Ar as the sputtering gas. Further, if a suitable amount of Xe or Kr is added to these sputtering gases, then the internal stresses in the films formed can be relieved, and peeling can be prevented. The resistivity of an α-phase Ta film is about 20 μΩcm and it can be suitably used in the gate electrode, but a β-phase Ta film has a resistivity of about 180 μΩcm and it is unsuitable for the gate electrode. A TaN film possesses a crystal structure which is close to the α-phase, and therefore the α-phase Ta film is easily obtained provide that a Ta film is formed on the TaN film. Note that although not shown in the figures, it is effective to form a silicon film doped by phosphorus (P), with a thickness of about 2 to 20 nm, below the conductive film (A) 111. By doing so, along with improving the adhesiveness of the conductive film formed on the silicon film and preventing oxidation, microscopic amounts of alkaline metal elements contained in the conductive layer (A) or in the conductive layer (B) can be prevented from diffusing into the gate insulating film 110. Whichever is done, it is preferable that the resistively of the conductive layer (B) be in the range of 10 to 500 μΩcm.

Next, a photoresist mask 113 is formed, and the conductive layer (A) 111 and the conductive layer (B) 112 are etched together, forming gate electrodes 114 and 115. For example, etching can be performed by dry etching using a mixed gas of CF₄ and O₂, or using Cl₂ gas, at a reaction pressure between 1 and 20 Pa. The gate electrodes 114 and 115 are formed from conductive layers 114a and 115a, made from the conductive layer (A), and from conductive layers 114band 115b, made from the conductive layer (B), respectively. The gate electrode 115 of the n-channel TFT overlaps a portion of the impurity region 109 through the gate insulating film 110. Further, it is possible to form the gate electrode from only the conductive layer (B). (FIG. 2B)

An impurity region 117 is formed next as a source region and a drain region of the p-channel TFT. Here, an impurity element that imparts p-type conductivity is added with the gate electrode 114 as a mask, and the impurity region is formed in a self-aligning manner. At this point, the island-like semiconductor layer that forms the n-channel TFT is covered by a photoresist mask 116. The impurity region 117 is then formed by ion doping using diborane (B₂H₆). The boron (B) concentration of this region is made to be from 3×10²⁰ to 3×10²¹ atoms/cm³. The concentration of the impurity element for imparting p-type conductivity contained in the impurity region 117 is referred to as (p⁺) throughout this specification. (FIG. 2C)

Next formation of an impurity region 118 which forms a source region or a drain region of the n-channel TFT is performed. Ion doping using phosphine (PH₃) is performed here, and the phosphorus (P) concentration is set to between 1×10²⁰ and 1×10²¹ atoms/cm³ in this region. The concentration of the impurity element for imparting n-type conductivity contained in the impurity region 118 is referred to as (n⁺) throughout this specification. Phosphorus (P) is simultaneously added to the impurity region 117, but compared to the concentration of boron (B) already added at the previous step, the concentration of phosphorus (P) added to the impurity region 117 is about one-third to one-half of that of boron, and therefore the p-type conductivity is ensured and no influence is imparted to the TFT characteristics.

Thereafter, a step of activating the impurity elements which impart n-type or p-type conductivity and have been added at the respective concentrations is performed by thermal annealing. An annealing furnace may be used at this step. In addition, laser annealing or rapid thermal annealing (RTA) can also be employed. The annealing process is performed at 400 to 700° C., typically 500 to 600° C. in a nitrogen atmosphere which has an oxygen concentration of 1 ppm or less, preferably 0.1 ppm or less. Heat treatment is performed for 4 hours at 550° C. in this embodiment. Further, it is appropriate to form a protective insulating film 119 of 50 to 200 nm thickness from a silicon oxynitride film or a silicon oxide film before annealing. It is preferred that the hidrogenated and nitrated silicon oxide film is formed under the condition #1883 or #1884 shown in Table 1. In this case, however, the film may be formed in-accordance with #1876 without causing any problem.

After the activation step, additional heat treatment is performed for 1 to 12 hours at 300 to 500° C. in an atmosphere containing hydrogen of between 3 and 100%, hydrogenating the island-like semiconductor layers. This step is for terminating dangling bonds in the semiconductor layers by thermally excited hydrogen. Plasma hydrogenation (using hydrogen excited by a plasma) may be performed as another means of hydrogenation. (FIG. 2E)

A hydrogenated silicon oxynitride film is then additionally deposited on the protective insulating film under the #1883 or the #1884 conditions shown in Table 1, forming an interlayer insulating film 120. The hydrogenated silicon oxynitride film is formed with a thickness of 500 to 1500 nm (preferably between 600 and 800 nm) in Embodiment 1 by introducing SiH₄ at 8.4 Pa·1/sec, N₂O at 200 Pa·1/sec, and H₂ at 844 Pa·1/sec, setting the reaction pressure to 40 Pa, the substrate temperature to 400° C., and the electric discharge power density to 0.4 W/cm².

Contact holes are then formed in the interlayer insulating layer 120 and the protective insulating layer 119, reaching the source region or the drain region of the TFT. Thus, source wirings 121 and 124, and drain wirings 122 and 123 are formed. Although not shown in the figures, in this embodiment, these electrodes are laminate films with a three layer structure of a 100 nm Ti film, a 300 nm aluminum film containing Ti, and a 150 nm Ti film formed in succession by sputtering.

Next, a silicon nitride film or a silicon oxynitride film is formed with a thickness of between 50 and 500 nm (typically from 100 to 300 nm) as a passivation film 125. If hydrogenation processing is performed in this state, then a desirable result of making the TFT characteristics better can be obtained. For example, it is appropriate to perform heat treatment for between 1 and 12 hours at 300 to 500° C. in an atmosphere containing 3 to 100% hydrogen. If the passivation film 125 is formed of a dense silicon nitride film and heat treatment is performed in this temperature range, then the hydrogen contained in the hydrogenated silicon oxynitride film forming the interlayer insulating film 120 is released, and the diffusion of hydrogen is prevented on the upper layer side by its being capped by the dense silicon nitride film. Therefore the released hydrogen preferentially diffuses to the lower layer side. Hydrogenation of the island-like semiconductor layers 104 and 105b can thus be performed by the hydrogen released from the hydrogenated silicon oxynitride film. Hydrogen is similarly released from the hydrogenated silicon oxynitride film used for the base film, and therefore the island-like semiconductor layers 104 and 105b are hydrogenated from both the lower and upper sides. Further, a similar result can be obtained by using plasma hydrogenation for the hydrogenation process.

An n-channel TFT 134 and a p-channel TFT 133 are thus completed on the substrate 101. The p-channel TFT 133 has a channel forming region 126, a source region 127, and a drain region 128 in the island-like semiconductor layer 104. The n-channel TFT 134 has a channel forming region 129, an LDD region 130 overlapping the gate electrode 115 (this type of LDD region is hereafter referred to as an Lov region), a source region 132, and a drain region 131 in an island-like semiconductor layer 105. The length of the Lov region in the channel length direction is set between 0.5 and 3.0 μm (preferably from 1.0 to 1.5 μm) for a channel length of 3 to 8 μm. Single gate structures are taken for the respective TFTs in FIGS. 2A to 2F, but double gate structures may also be used, and multi-gate structures in which a plural number of gate electrodes are formed may also be used without hindrance. (FIG. 2F)

The characteristics of a TFT manufactured in this way are evaluated. TFT characteristics which are important for normal operation of a circuit formed using TFTs at a desired drive voltage include characteristics such as Vth, the S value, and the electric field effect mobility, and particular attention is paid to Vth and the S value here. The TFT size is as follows: a channel length L=8 μm, and a channel width W=8 μm, for both the p-channel and n-channel TFTs, and an Lov=2 μm for the LDD region in the n-channel TFT as an LDD region.

As a result, the S value can be made from 0.10 to 0.30 V/dec, Vₜₕ can be made from 0.5 to 2.5 V, and the electric field effect mobility can be made from 120 to 250 cm²/V·sec in the n-channel TFT in the completed TFT. Further, in the p-channel TFT of the completed TFT, the S value can be made from 0.10 to 0.30 V/dec, Vₜₕ can be made from −2.5 to −0.5 V, and the electric field effect mobility can be made from 80 to 150 cm²/V·sec. By forming the base film, the gate insulating film, and the protective insulating film or the interlayer insulating film of the TFT from a hydrogenated silicon oxynitride film manufactured from SiH₄, N₂O, and H₂, and, by suitably setting the composition beginning with the amount of hydrogen contained, these characteristics can be obtained with good reproducibility.

### Embodiment 2

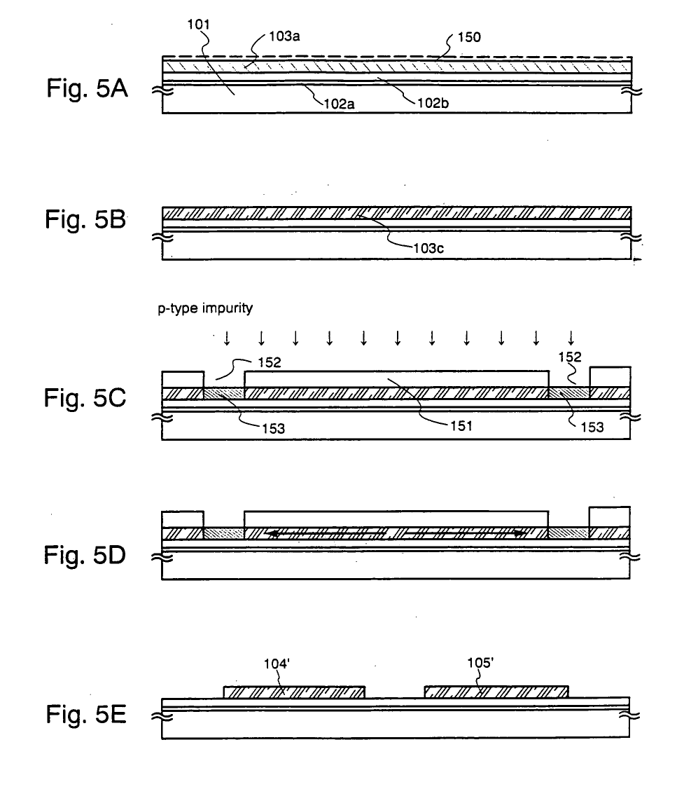

The method of manufacturing a crystalline semiconductor film that serves as an active layer of a TFT is not limited to laser annealing; laser annealing and thermal annealing may be jointly used. Further, the crystallization method disclosed in Japanese Patent Application Laid-open No. Hei 7-130652, which uses a catalytic element, can also be applied to the crystallization by thermal annealing. This method is explained with reference to FIGS. 5A to 5E.

As shown in FIG. 5A, a silicon oxynitride film 102a and a hydrogenated silicon oxynitride film 102b are formed on a substrate 101, similar to Embodiment 1. An amorphous semiconductor film 103a is then formed with a thickness of 25 to 80 nm by a method such as plasma CVD or sputtering. For example, a 55 nm thick amorphous silicon film is formed. An aqueous solution containing 10 ppm by weight of a catalytic element is then applied by spin coating, forming a layer 150 containing the catalytic element (not shown in the figures). Elements such as nickel (Ni), germanium (Ge), iron (Fe), palladium (Pd), tin (Sn), lead (Pb), cobalt (Co), platinum (Pt), copper (Cu), and gold (Au) may be used as the catalytic element. In addition to spin coating, the catalytic element containing layer 150 may also be made by forming a 1 to 5 nm thick layer of the above catalytic elements by sputtering or vacuum evaporation.

In the crystallization step shown in FIG. 5B, heat treatment is first performed for approximately 1 hour at between 400 and 500° C., making the amount of hydrogen contained in the amorphous silicon film 5 atomic % or less. Thermal annealing is then performed in a nitrogen atmosphere at 550 to 600° C. for between 1 and 8 hours using an annealing furnace. A crystalline semiconductor film (crystalline silicon film) 103c can thus be obtained through the above steps. However, if the crystalline semiconductor film 103c, manufactured by thermal annealing up through the present step, is observed microscopically by a means such as a transmission electron microscope, then it is seen that the film is composed of a multiple number of grains, and that the size and arrangement of the crystals are not uniform, but random. Further, from observation of spectrum using a Raman spectroscopy and from macroscopic observation using an optical microscope, it is discerned that amorphous region remain locally.

In order to further enhance the crystallinity of the crystalline semi-conductor film 103c, it is effective to perform laser annealing at this stage. In laser annealing the crystalline semiconductor film 103c is recrystallized after once being made into a melted state, and therefore the above aim of increasing crystallinity can be achieved. For example, an XeCl excimer laser (wavelength 308 nm) is used to form a linear shape beam by an optical system, the oscillation frequency is set between 5 and 50 Hz, the energy density is set from 100 to 500 mJ/cm², and the beam is irradiated with an overlap ratio of the linear shape beam of between 80 and 98%. The crystallinity of the crystalline semiconductor film 103c can thus be made even higher. However, the concentration of the catalytic element remaining in the surface of the crystalline semiconductor film 103c in this state is between 3×10¹⁰ and 2×10¹¹ atoms/cm³.

One of effective means is to then continue by performing the gettering process disclosed in Japanese Patent Application Laid-open No. Hei 10-247735. The concentration of the catalytic element in the crystalline semiconductor film 103c can be reduced to 1×10¹⁷ atoms/cm³ of less, preferably to 1×10¹⁶ atoms/cm³ at this gettering step. First, as shown in FIG. 5C, a mask insulating film 151 is formed with a thickness of 150 nm on the surface of the crystalline semiconductor film 103c, and openings 152 are formed by patterning, exposing a portion of the crystalline semiconductor film. A phosphorus addition step is then performed, forming phosphorus containing regions 152 in the crystalline semiconductor film 103c. If heat treatment is performed in this state, as shown in FIG. 5D, in a nitrogen atmosphere at 500 to 800° C. (preferably between 500 and 550° C.) for 5 to 24 hours, for example at 525° C. for 12 hours, then the phosphorus containing regions 153 work as gettering sites, and the catalytic element remaining in the crystalline silicon film 103c can be segregated into the phosphorus containing regions 153. By then removing the mask insulating films 152 and the phosphorus containing regions 153, forming island-like semiconductor layers 104′ and 105′, as shown in FIG. 5E, a crystalline silicon film can be obtained in which the concentration of the catalytic element used at the crystallization step is reduced to 1×10¹⁷ atoms/cm³ or less.

If subsequent steps are performed in accordance with the steps from FIG. 1C of Embodiment 1, then TFTs can be completed using the island-like semiconductor layers 104′ and 105′. Further, the gettering step is not limited to the methods of Embodiment 2, and there is also a method of performing gettering at the same time as step of activating source regions and drain regions, as will be described later.

### Embodiment 3

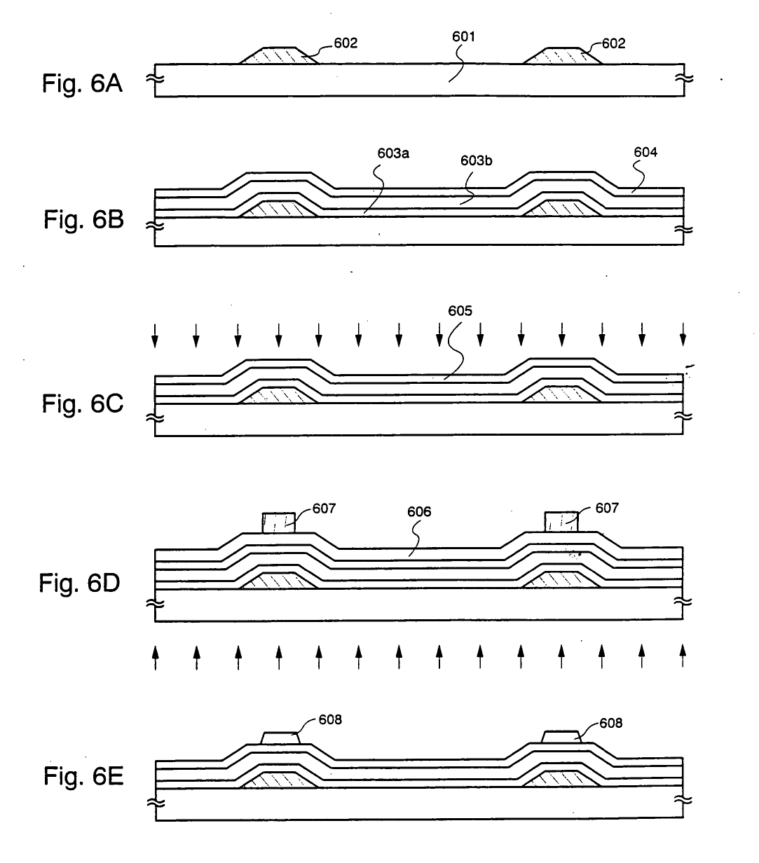

Embodiment 3 is explained with reference to FIGS. 6A to 8D. First, a glass substrate, for example a Corning Corp. #1737 substrate, is prepared as a substrate 601. Gate electrodes 602 is then formed on the substrate 601. Sputtering is used here to form a tantalum (Ta) film with a thickness of 200 nm. Further, a two layer structure of a tantalum nitride (TaN) film (film thickness 50 nm) and a tantalum (Ta) film (film thickness 250 nm) may be used as the gate electrode 602. The Ta film is formed by sputtering using Ar gas and with Ta as a target, and if sputtering is performed with a gas mixture in which Xe gas is added to the Ar gas, then the absolute value of the internal stress can be made to be 2×10⁸ Pa or less. (FIG. 6A)

A gate insulating film 603 and an amorphous semiconductor layer 604 are then formed in order successively, without exposure to the atmosphere. The gate insulating film 603 is formed of a nitrogen rich silicon oxynitride film 603a formed by plasma CVD with a thickness of 25 nm, and a hydrogenated silicon oxynitride film 603b formed on top to a thickness of 125 nm, manufactured in accordance with the #1884 conditions shown in Table 1. Further, the amorphous semiconductor layer 604 is formed to a thickness of 20 to 100 nm, preferably between 40 and 75 nm, by using plasma CVD. (FIG. 6B) Heat treatment is then performed for one hour at 450 to 550° C. using an annealing furnace. Hydrogen is released from the amorphous semiconductor layer 604 through the heat treatment, so that the amount of hydrogen remaining is reduced to 5 atomic % or less. A step of crystallizing the amorphous semiconductor layer 604 is performed next, forming a crystalline semiconductor layer 605. Laser annealing or thermal annealing may be used at this crystallization step. In the laser annealing method, crystallization is performed by, for example, using a KrF excimer laser light (wavelength 248 nm), forming a linear shape beam, setting the pulse oscillation frequency to 30 Hz, the laser energy density to between 100 and 500 mJ/cm², and the overlap ratio of the linear beam to 96%, to crystallize the amorphous semiconductor layer. (FIG. 6C) Furthermore, the method of crystallization explained in Embodiment 2 can also be applied.

A hydrogenated silicon oxynitride film 606, for protective a channel forming region, is formed next in close contact with the crystalline semiconductor layer 605. This hydrogenated silicon oxynitride film 606 is also manufactured in accordance with the #1884 conditions shown in Table 1, with a thickness of 200 nm. If the plasma cleaning process described in Embodiment 1 is performed in the reaction chamber of the plasma CVD apparatus before depositing the hydrogenated silicon oxynitride film 606, processing the surface of the crystalline semiconductor layer 605, then fluctuation in Vₜₕ of the TFT characteristic can be reduced. Resist masks 607 is formed next in contact with the hydrogenated silicon oxynitride film 606 by patterning using back face exposure. The gate electrodes 602 here serve as masks, and the resist masks 607 are formed in a self-aligning manner. As shown in the figures, the size of the resist masks becomes slightly smaller than the width of the gate electrodes due to wraparound of light. (FIG. 6D)

The hydrogenated silicon oxynitride film 606 is etched using the resist masks 607, forming the channel protective films 608, after which the resist masks 607 are removed. The surface of the regions of the crystalline semiconductor layer 605 which are not in contact with the channel protective films 608 are exposed at this step. Along with fulfilling a role of preventing the addition of impurities to the channel forming region during a later impurity addition step, the channel protective films 608 are effective in reducing the interface level density of the crystalline semiconductor layer. (FIG. 6E)

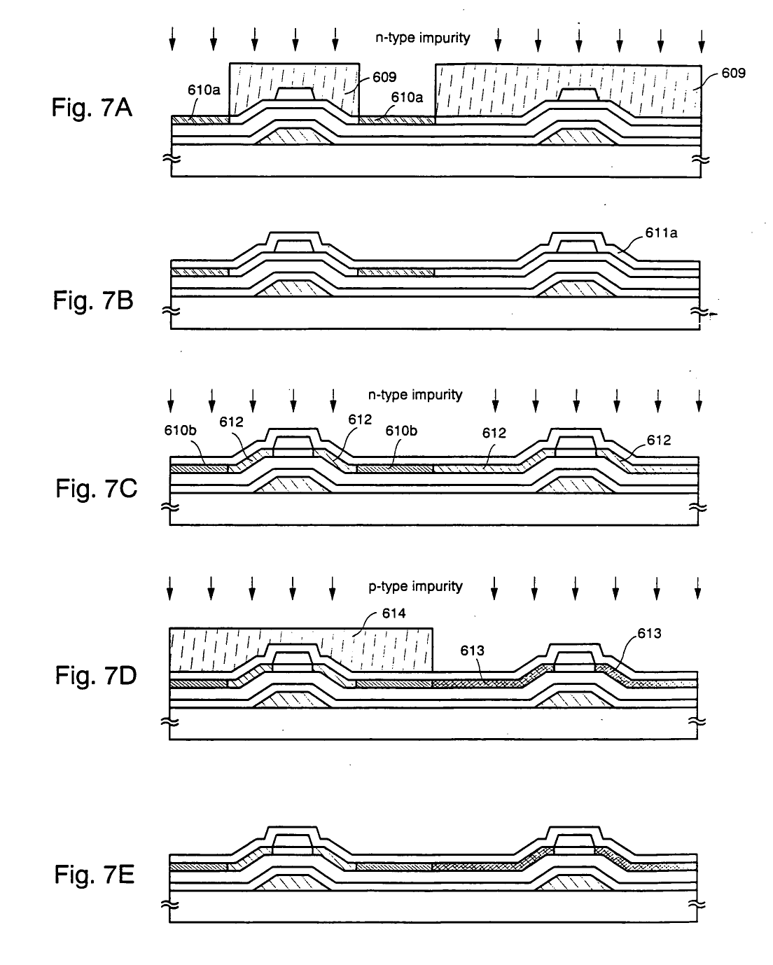

Next, a resist mask 609 is formed covering a p-channel TFT and a portion of an n-channel TFT by patterning using a photomask, and a step of adding an impurity element which imparts n-type conductivity to the exposed regions of the surface of the crystalline semiconductor layer 605 is performed. n⁺ regions 610a are then formed. Phosphorus (P) is added here by ion doping using phosphine (PH₃), with a dosage of 5×10¹⁴ atoms/cm² and an acceleration voltage of 10 keV. Furthermore, the pattern of the above resist masks 609 determines the width of the n⁺ regions 610a by being suitably set by the operator, and it is also possible to make an n⁻ region and a channel forming region with a desired width. (FIG. 7A)

After removing the resist masks 609, a protective insulating film 611a is formed. This film is also formed of a hydrogenated silicon oxynitride film manufactured in accordance with the #1884 conditions shown in Table 1, with a thickness of 50 nm. (FIG. 7B) A step of adding an impurity element which imparts n-type conductivity to the crystalline semiconductor layer, on which the protective insulating film 611a is formed, is performed next, forming n⁻ regions 612. Note that it is necessary to consider the thickness of the protective insulating film 611a and set suitable conditions in order to add the impurity through the protective insulating film 611a and into the crystalline semiconductor layer below the film 611a. The dosage is set to 3×10¹³ atoms/cm² and the acceleration voltage is set to 60 keV here. The n⁻ regions 612 thus formed between the n⁺ region 610b and the channel forming region function as LDD regions. (FIG. 7C)

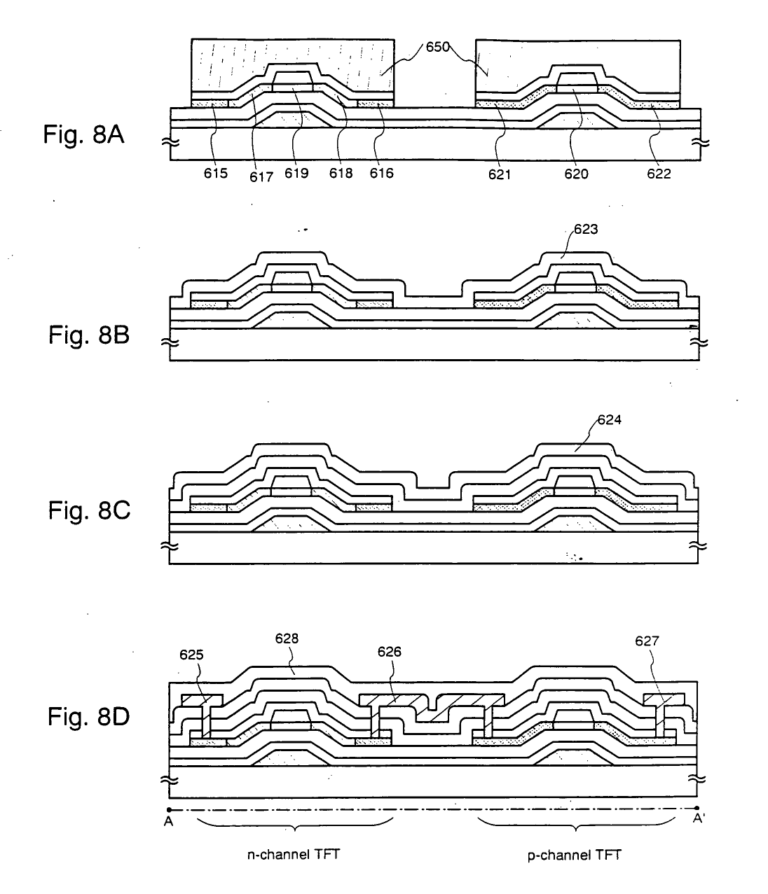

A resist mask 614 is formed next, covering the n-channel TFT, and a step of adding an impurity element which imparts p-type conductivity to the region in which the p-channel TFT is formed is performed. Boron (B) is added here by ion doping using diborane (B₂H₆). The dosage is set to 4×10¹⁵ atoms/cm² and the acceleration voltage is set to 30 keV, forming a p⁺ region 613. (FIG. 7D) A step of activating the impurity element is then performed by laser annealing or thermal annealing. (FIG. 7E) The channel forming regions 608 and the protective insulating films 611a are left as is, and the crystalline semiconductor layer is etched into a desired shape by a known patterning technique by using resist 650 as masks. (FIG. 8A)

Thus, through the above steps, a source region 615, a drain region 616, LDD regions 617 and 618, and a channel forming region 619 are formed in the n-channel TFT, and a source region 621, a drain region 622, and a channel forming region 620 are formed in the p-channel TFT. Next, a first interlayer insulating film 623 is formed covering the n-channel TFT and the p-channel TFT. A hydrogenated silicon oxynitride film manufactured in accordance with the #1883 conditions shown in Table 1 is formed to a thickness of between 100 and 500 nm for the first interlayer insulating film 623. (FIG. 8B) A second interlayer insulating film 624 is then formed to a similar thickness of 100 to 500 nm of a hydrogenated silicon oxynitride film manufactured in accordance with the #1876 conditions shown in Table 1. (FIG. 8C)

A first hydrogenation step is performed in this state. This process may be performed, for example, in a 3 to 100% hydrogen atmosphere at 300 to 550° C., preferably between 350 and 500° C., for 1 to 12 hours. Alternatively, processing may be performed for between 10 and 60 minutes at a similar temperature in an atmosphere containing hydrogen made into a plasma. Hydrogen contained in the first interlayer insulating film, and hydrogen supplied to the second interlayer insulating film from the gas phase by the above heat treatment atmosphere, diffuses due to the present heat treatment process, a portion of the hydrogen reaches the semiconductor layer, and therefore hydrogenation of the crystalline semiconductor layer can effectively be performed.

A predetermined resist mask is formed next, and contact holes reaching the source regions and the drain regions of the respective TFTs are formed in the first interlayer insulating film 623 and in the second interlayer insulating film 624. Source electrodes 625 and 627, and a drain electrode 626 are then formed. Although not shown in the figures, a three layer structure electrode of a 100 nm Ti film, a 300 nm Al film containing Ti, and a 150 nm film formed successively by sputtering is used as the electrodes in embodiment 3. (FIG. 8D)

In addition, a step of forming a passivation film 628 is performed. The passivation film is made by plasma CVD from a silicon oxynitride film formed using SiH₄, N₂O, and NH₃, or from a silicon nitride film manufactured by using SiH₄, N₂O, and NH₃. A plasma hydrogenation process is performed first, before forming the film, by introducing a substance such as N₂O, N₂, or NH₃. The hydrogen made into a plasma in the gas phase is supplied into the second interlayer insulating film, and if the substrate is heated to between 200 and 500° C., then the hydrogen can also be made to diffuse into the first interlayer insulating film and to layers below the first interlayer insulating film, thereby carrying out a second hydrogenation step. The manufacturing conditions of the passivation film are not in particular limited, but it is preferable to form a dense film. Finally, a third hydrogenation step is performed by performing heat treatment for 1 to 12 hours at between 300 and 550° C. in an atmosphere containing hydrogen or nitrogen. At this point, hydrogen diffuses from the passivation film 628 to the second interlayer insulating film 624, from the second interlayer insulating film 624 to the first interlayer insulating film 623, and from the first interlayer insulating film 623 to the crystalline semiconductor layer, and hydrogenation of the crystalline semiconductor layer can effectively be carried out. Hydrogen also is released into the gas phase from within the films, but a dense passivation film prevent the release to a certain extent. If hydrogen has been supplied into the heat treatment atmosphere, then this can compensate for the hydrogen released.

The p-channel TFT and the n-channel TFT of reverse stagger type structure can thus be formed on the same substrate through the above steps. Also in the reverse stagger type TFT, by applying the hydrogenated silicon oxynitride film of the present invention to insulating films such as the gate insulating film 603b, the channel protective film 608, and the protective insulating film 611, the S value can be made from 0.10 to 0.30 V/dec, Vₜₕ can be made from 0.5 to 2.5 V, and the electric field effect mobility can be made from 120 to 250 cm²/V·sec in the n-channel TFT of the completed TFT. Further, in the p-channel TFT of the completed TFT, the S value can be made from 0.10 to 0.30 V/dec, Vₜₕ can be made from −2.5 to −0.5 V, and the electric field effect mobility can be made from 80 to 150 cm²/V·sec. These characteristics are caused by the fact that the defect level density of the hydrogenated silicon oxynitride film, such as neutral defects and electric charge defects, is low and by the fact that the interface level density with the semiconductor layer is low.

### Embodiment 4

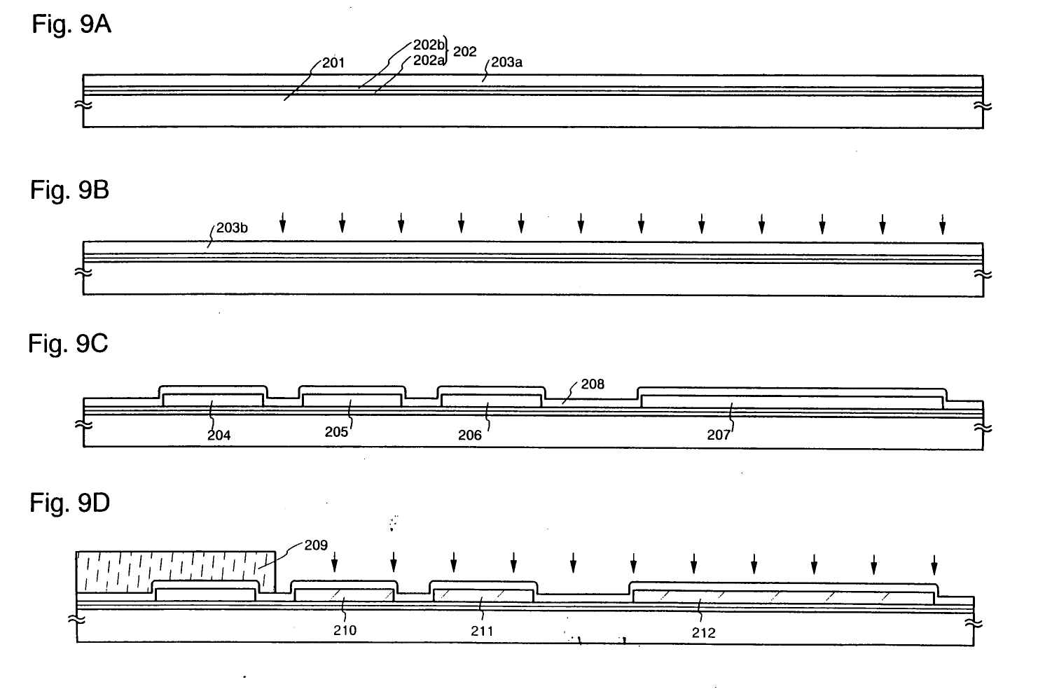

Embodiment 4 of the present invention is explained with reference to FIGS. 9A to 13. Here, a detailed explanation is made of a method of manufacturing on the same substrate a pixel TFT of a pixel portion, and driver circuit TFTs formed in the periphery of the pixel portion. Note that, in order to simplify the explanation, a CMOS circuit, which is the basic circuit for control circuits such as a shift register circuit and a buffer circuit, and an n-channel TFT forming a sampling circuit are shown in the figures.

A barium borosilicate glass substrate or an alumino borosilicate glass substrate is used as a substrate 201 in FIG. 9A. An alumino borosilicate glass substrate is used in embodiment 4. A base film 202 is formed on a surface of the substrate 201 on which TFTs will be formed. In order to prevent diffusion of impurity elements such as alkaline metal elements from the substrate 201, the base film 202 is formed of a silicon oxynitride film 202a with a thickness of 50 nm manufactured by plasma CVD from SiH₄, NH₃, and N₂O. In addition, in order to maintain a good interface with a semiconductor layer, a hydrogenated silicon oxynitride film 202b with a thickness of 100 nm and manufactured, in accordance with the #1884 conditions shown in Table 1, from SiH₄, N₂O, and H₂, is layered on the film 202a, thereby forming the base film 202.

A semiconductor film 203a having an amorphous structure is formed next, with a thickness of between 25 and 80 nm (preferably between 30 and 60 nm), by a known method such as plasma CVD or sputtering. In this embodiment, an amorphous silicon film is formed to have a thickness of 55 nm by plasma CVD. The base film 202 and a semiconductor layer 203a having an amorphous structure may be formed successively, because the same method can be used to form both films. By not exposing the surface to the atmosphere after forming the base film, it becomes possible to prevent contamination of the surface, and fluctuation in the characteristics of the manufactured TFT, and the change in the threshold voltage, can be reduced. (FIG. 9A)

A crystalline semiconductor layer 203b is then formed from the semiconductor layer 203a having an amorphous structure, using a known crystallization technique. An amorphous silicon film is used here for the semiconductor layer 203a having the amorphous structure, so that a crystalline silicon film is formed from this film. Laser annealing or thermal annealing (solid phase growth methods) may be employed for the crystallization, but a crystalline semiconductor layer 203b is formed here by a crystallization method using a catalytic element in accordance with the technique disclosed in Japanese Patent Application Laid-open No. Hei 7-130652 mentioned in Embodiment 2. First, an aqueous solution containing 10 ppm by weight of a catalytic element is applied by spin coating, forming a layer containing the catalytic element (not shown in the figures). Elements such as nickel (Ni), germanium (Ge), iron (Fe), palladium (Pd), tin (Sn), lead (Pb), cobalt (Co), platinum (Pt), copper (Cu), and gold (Au) may be used as the catalytic element. In the crystallization step, heat treatment is first performed for approximately 1 hour at between 400 and 500° C., making the amount of hydrogen contained in the amorphous silicon film 5 atomic % or less. Thermal annealing is then performed in a nitrogen atmosphere at 550 to 600° C. for 1 to 8 hours using an annealing furnace. A crystalline silicon film can thus be obtained through the above steps. The concentration of the catalytic element remaining on the surface in this state is between 3×10¹⁰ and 2×10¹¹ atoms/cm³. Laser annealing may also be performed in conjunction with thermal annealing in order to improve the crystallization ratio. For example, an XeCl excimer laser (wavelength is 308 nm) is used to form a linear shape beam by an optical system, the oscillation frequency is set between 5 and 50 Hz, the energy density is set from 100 to 500 mJ/cm², and the beam is irradiated with an overlap ratio of the linear shape beam of between 80 and 98%. The crystalline semiconductor layer 203b is thus obtained. (FIG. 9B)

The crystalline semiconductor layer 203b is then etched and partitioned into island-shapes, forming island-like semiconductor layers 204 to 207, which serve as active layers. A mask layer 208 is then formed from a silicon oxide film by plasma CVD, low pressure CVD, or sputtering to a thickness of between 50 and 100 nm. For example, the silicon oxide film is formed by low pressure CVD using a mixed gas of SiH₄ and O₂ and by heating it to 400° C. at a pressure of 266 Pa. (FIG. 9C)

Channel doping is then performed. A photoresist mask 209 is formed first, and boron (B) is added as an impurity element that imparts p-type conductivity to the entire surface of the island-like semiconductor layers 205 to 207 that form the n-channel TFT, at a concentration of about 1×10¹⁶ to 5×10¹⁷ atoms/cm³, with the aim of controlling the threshold voltage. Ion doping may be used for the addition of boron (B), and boron (B) can be added at the same time as the amorphous silicon film is formed. It is not always necessary to add boron (B) here, but it is preferable to form semiconductor layers 210 to 212 with added boron in order to place the threshold voltage of the n-channel TFT within a predetermined range. The method shown in Embodiment 2 or 3 may also be used for this channel doping step. (FIG. 9D)

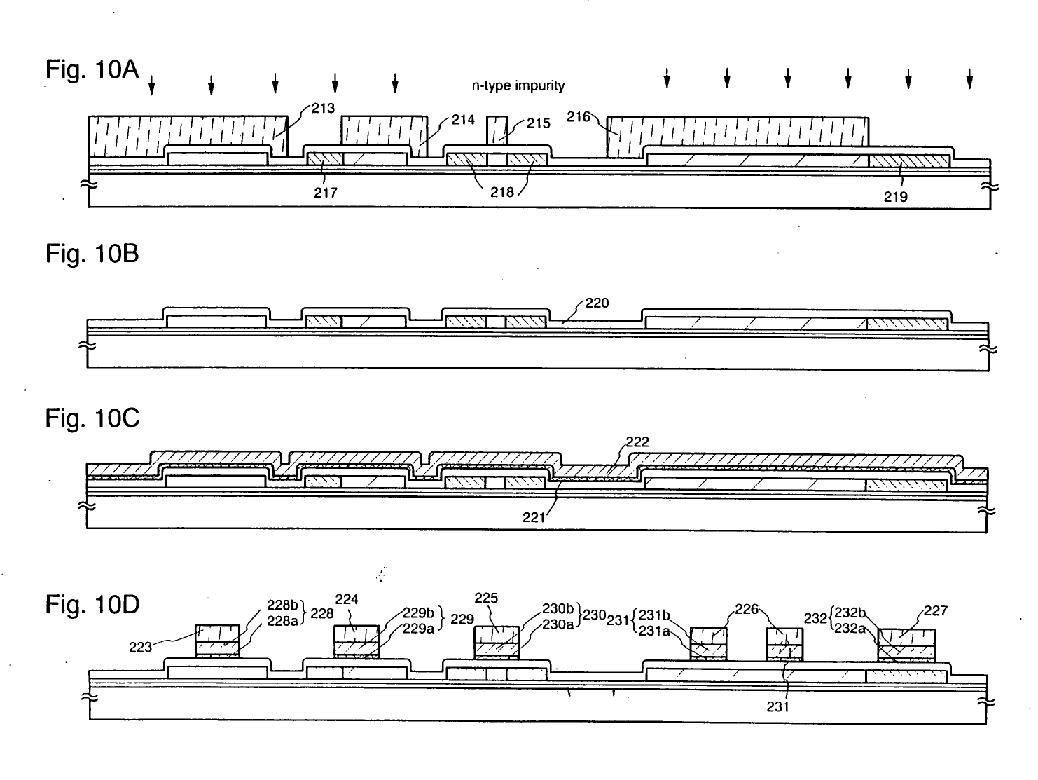

In order to form an LDD region of the n-channel TFT of the driver circuit, an impurity element that imparts n-type conductivity is selectively added to the island-like semiconductor layers 210 and 211. Photoresist masks 213 to 216 are formed in advance for this purpose. To add phosphorus (P), ion doping using phosphine (PH₃) is applied here. The phosphorus (P) concentrations of formed impurity regions (n⁻) 217 and 218 are set to between 1×10¹⁷ and 5×10¹⁷ atoms/cm³, respectively. Further, an impurity region 219 is a semiconductor layer for forming a storage capacitor in the pixel portion, and phosphorus (P) is added to this region at the same concentration. (FIG. 10A)

The mask layer 208 is removed next by a substance such as hydrofluoric acid, and a step of activating the impurity elements added at the steps illustrated in FIG. 9D and FIG. 10A is performed. The activation can be performed by thermal annealing for 1 to 4 hours at between 500 and 600° C. in nitrogen atmosphere, or by laser annealing. Further, both methods may be performed together. Laser activation is used in this embodiment, and KrF excimer laser light (wavelength 248 nm) formed into a linear shape beam is used, with an oscillation frequency of 5 to 50 Hz and the energy density set to between 100 and 500 mJ/cm², and this is scanned with an overlap ratio for the linear shape beam of 80 to 98%, processing the entire surface of the substrate on which the island-like semiconductor layers are formed. Note that there are no specific limitation placed on the laser light irradiation conditions, and that the operator may set them suitably.

A gate insulating film 220 is then formed with a thickness of 40 to 150 nm by using plasma CVD. A multi-chamber separation type plasma CVD apparatus is used here, and plasma cleaning is performed on the substrate on which the island-like semiconductor layers are formed in the same reaction chamber as that in which a gate insulating film is formed, or within a reaction chamber dedicated to plasma cleaning, before deposition of the gate insulating film. The plasma cleaning process is performed for 2 minutes by introducing hydrogen at 338 Pa·1/sec, and then generating a plasma by setting the pressure to 20 Pa and the high frequency power to 0.2 W/cm². Alternatively, hydrogen may be introduced at 169 Pa·1/sec, oxygen at 169 Pa·1/sec, and a plasma may similarly be generated at a pressure of 40 Pa. The substrate temperature is set from 300 to 500° C., preferably at 400° C. By performing the plasma cleaning process on the surfaces of the island-like semiconductor layers 204, and 210 to 212 at this stage, contaminating matter such as adsorbed boron or phosphorus, or organic matter, can be removed. Also, hydrogen is adsorbed on the surface by the plasma cleaning, making it inactive. Furthermore, by introducing oxygen and N₂O at the same time, the topmost surface of the deposition surface, and its close vicinity, are oxidized, resulting in desirable actions such as a reduction in the interface level density of the interface with the gate insulating film. It is preferable to form the gate insulating film 220 in succession with the plasma cleaning process, without exposing the substrate 201 to the atmosphere, and the gate insulating film 220 is formed by introducing SiH₄ into the reaction chamber at 8.4 Pa·1/sec, N₂O at 203 Pa·1/sec, and H₂ at 211 Pa·1/sec, setting the substrate temperature to 400° C., the reaction pressure to 20 Pa, the electric discharge power density to 0.41 W/cm², and the electric discharge frequency to 60 MHz. (FIG. 10B)

A first conductive layer is formed next in order to form a gate electrode. A conductive layer (A) 221 made from a metallic nitride film having conductivity, and a conductive layer (B) 222 made from a metallic film are laminated in this embodiment. The conductive film (B) 222 is formed from tantalum (Ta) to a thickness of 250 nm, and the conductive layer (A) 221 is formed from tantalum nitride (TaN) to a thickness of 50 nm, by sputtering using Ta as a target. (FIG. 10C)

Photoresist masks 223 to 227 are formed next, and the conductive layer (A) 221 and the conductive layer (B) 222 are etched at the same time, forming gate electrodes 228 to 231 and a capacitor wiring 232. The gate electrodes 228 to 231 and the capacitor wiring 232 are formed, respectively, from conductive layers (A) 228a to 232a and conductive layers (B) 228b to 232b. The gate electrodes 229 and 230 formed in the driver circuit are formed to overlap a part of the impurity regions 217 and 218, through the gate insulating film 220, at this point. (FIG. 10D)

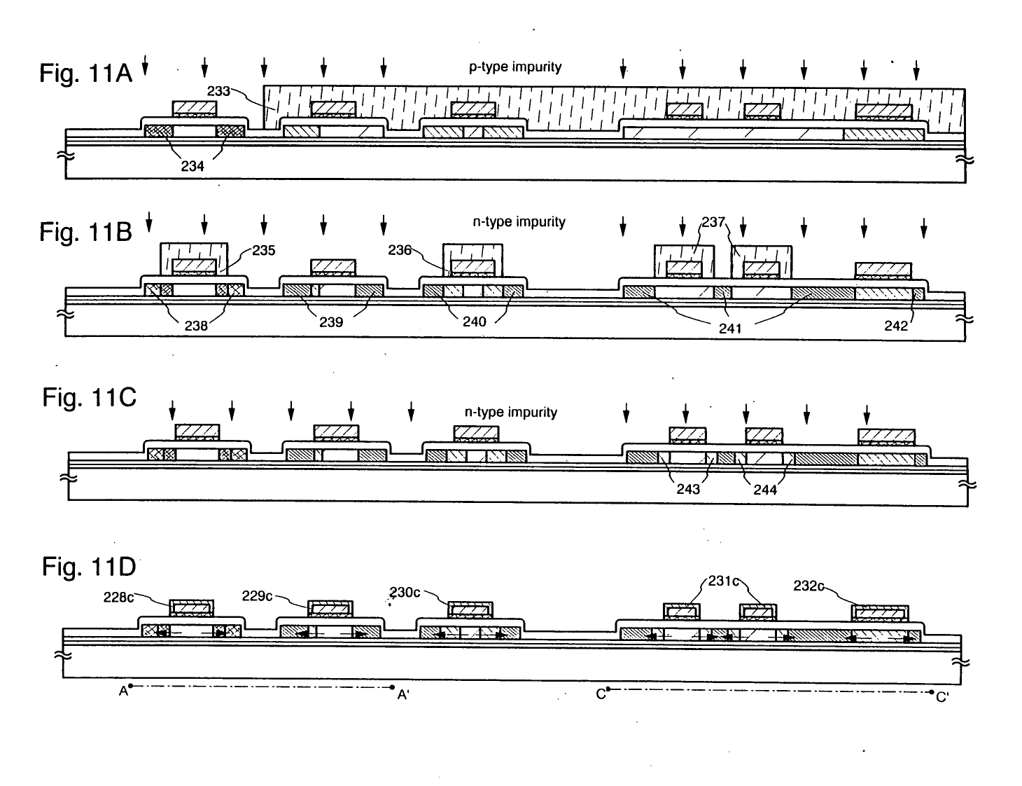

Next, in order to form a source region and a drain region of the p-channel TFT of the driver circuit, a step of adding an impurity element that imparts p-type conductivity is performed. Impurity regions are formed in a self-aligning manner here with the gate electrode 228 as a mask. The region in which the n-channel TFT is formed is covered with a photoresist mask 233. An impurity region (p⁺) 234 at a concentration of 1×10²¹ atoms/cm³ is then formed by ion doping using diborane (B₂H₆). (FIG. 11A)

Formation of impurity regions functioning as a source region or a drain region of the n-channel TFT is performed next. Resist masks 235 to 237 are formed, and an impurity element that imparts n-type conductivity is added, forming impurity regions 238 to 242. This is performed by ion doping using phosphine (PH₃), and the phosphorus (P) concentration of the impurity regions (n⁺) 238 to 242 is set to 5×10²⁰ atoms/cm³. Boron (B) is already contained in the impurity region 238 at a previous step, but in comparison, phosphorus (P) is added with a concentration of one-third to one-half that of the boron (B), and therefore the influence of phosphorus (P) need not be considered, and there is no influence imparted to the characteristics of the TFT. (FIG. 11B)

A step of adding an impurity that imparts n-type conductivity is then performed in order to form an LDD region of the n-channel TFT of the pixel portion. An impurity element that imparts n-type conductivity is added by ion doping in a self-aligning manner using the gate electrode 231 as a mask. The concentration of phosphorus (P) added is set to 5×10¹⁶ atoms/cm³, and this is a lower concentration than that of the impurity elements added at the steps illustrated in FIG. 10A, FIG. 11A, and FIG. 11B, forming, in practice, only impurity regions (n⁻) 243 and 244. (FIG. 11C)

A heat treatment step is performed next in order to activate the impurity elements which impart n-type or p-type conductivity and have been added at the respective concentrations. Thermal annealing using an annealing furnace, laser annealing, or rapid thermal annealing (RTA) can be employed for this step. The activation step is performed here using furnace annealing. The heat treatment step is performed in a nitrogen atmosphere in which the oxygen concentration is 1 ppm or less, preferably 0.1 ppm or less, at between 400 and 700° C., typically between 500 and 600° C., and is performed for 4 hours at 550° C. in this embodiment.

Through thermal annealing, the Ta films 228b to 232b forming the gate electrodes 228 to 231, and the capacitor wiring 232, come to have conductive films (C) 228c to 232c, made from TaN, formed to a thickness of 5 to 80 nm from the surfaces of the Ta films. In addition, when the conductive layers (B) 228b to 232b are tungsten (W), tungsten nitride (WN) is formed, and titanium nitride (TiN) can be formed when the conductive layers are titanium (Ti). Further, these can be formed similarly by exposing the gate electrodes 228 to 231 to a plasma atmosphere containing nitrogen using a substance such as nitrogen or ammonia. In addition, a step of hydrogenating the island-like semiconductor layers is performed by thermal annealing at 300 to 500° C. for between 1 and 12 hours in an atmosphere containing between 3 and 100% hydrogen. This step is the one for terminating dangling bonds in the semiconductor layers by thermally excited hydrogen. Plasma hydrogenation (using hydrogen excited by a plasma) may be performed as another means of hydrogenation.

In cases of manufacturing island-like semiconductor layers from an amorphous silicon film by a crystallization method using a catalytic element, as in this embodiment, a small amount (about 1×10¹⁷ to 1×10¹⁹ atoms/cm³) of the catalytic element remains within the island-like semiconductor layers. It is, of course, possible to complete the TFT in such a state, but it is preferable to remove the remaining catalytic element from at least the channel forming region. One of the means of removing the catalytic element is a means using gettering action of phosphorus (P). The concentration of phosphorus (P) necessary for gettering may be on a similar order as that of the impurity regions (n⁺) formed at the step illustrated in FIG. 11B, and the catalytic element can be segregated from the channel forming regions of the n-channel TFT and the p-channel TFT, into the impurity regions 238 to 242 to be gettered, by the thermal annealing at the activation step performed here. As a result, the catalytic element is segregated into the impurity regions 238 to 242 at a concentration of about 1×10¹⁷ and 1×10¹⁹ atoms/cm³. (FIG. 11D)

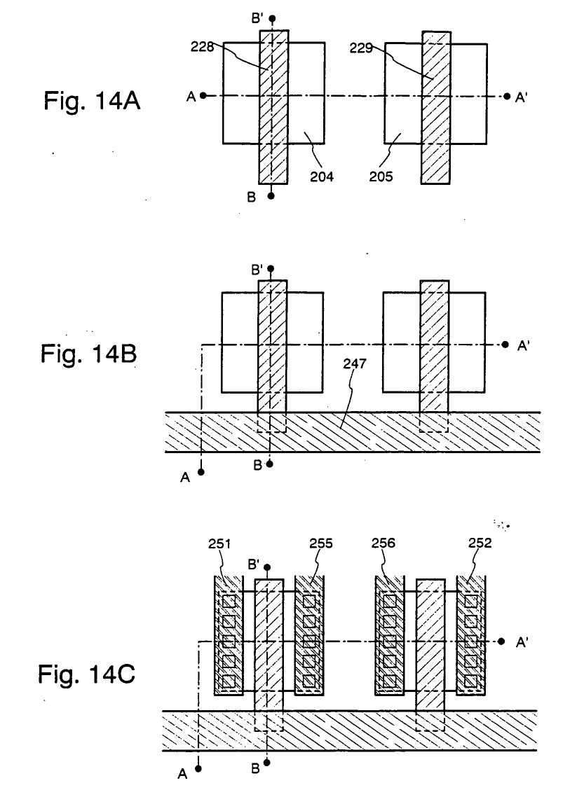

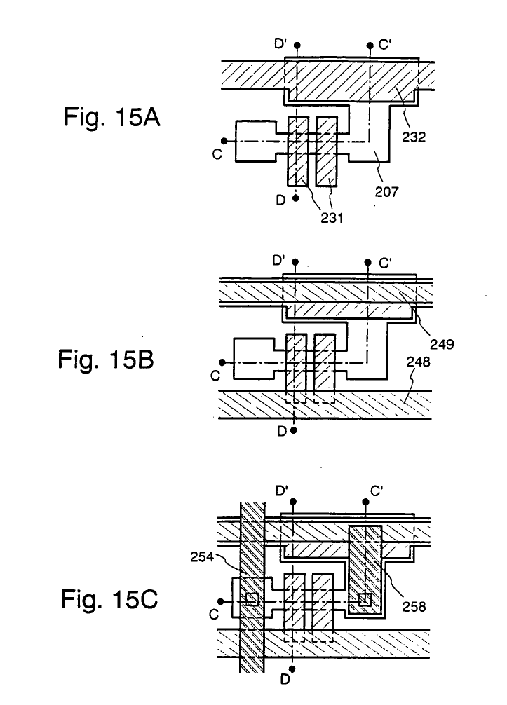

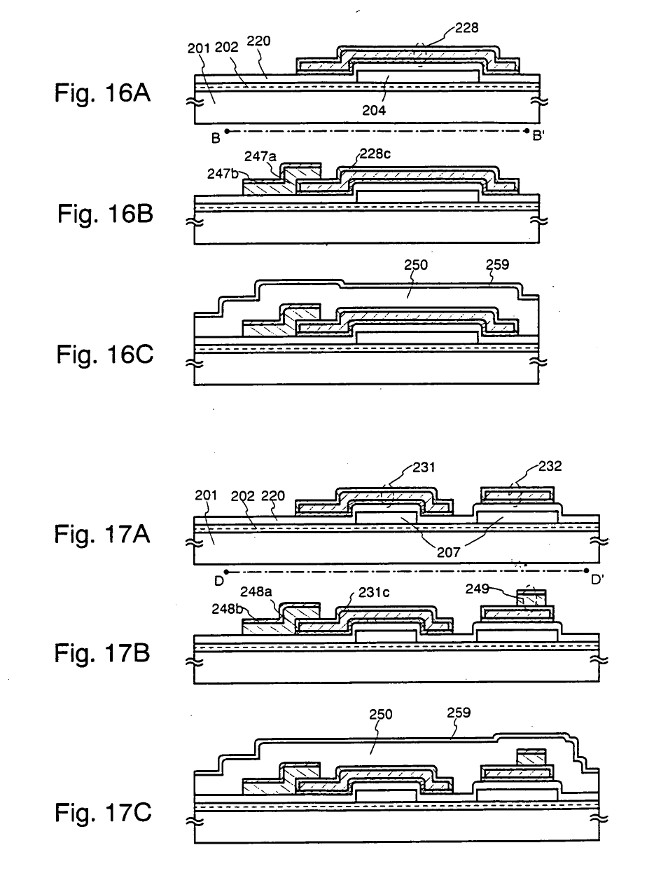

FIGS. 14A and 15A are top views of the TFTs up through the present step, and the cross sections taken along the line A-A′ and the line C-C′ correspond to A-A′ and C-C′, respectively, in FIG. 11D. Further, the cross sections taken along the line B-B′ and the line D-D′ correspond to the cross-sectional views of FIG. 16A and FIG. 17A. The gate insulating film is omitted from the top views of FIGS. 14A to 14C, and FIGS. 15A to 15C, but in the steps through here, at least the gate electrodes 228 to 231, and the capacitor wiring 232, are formed on the island-like semiconductor layers 204 to 207, as shown in the figures.

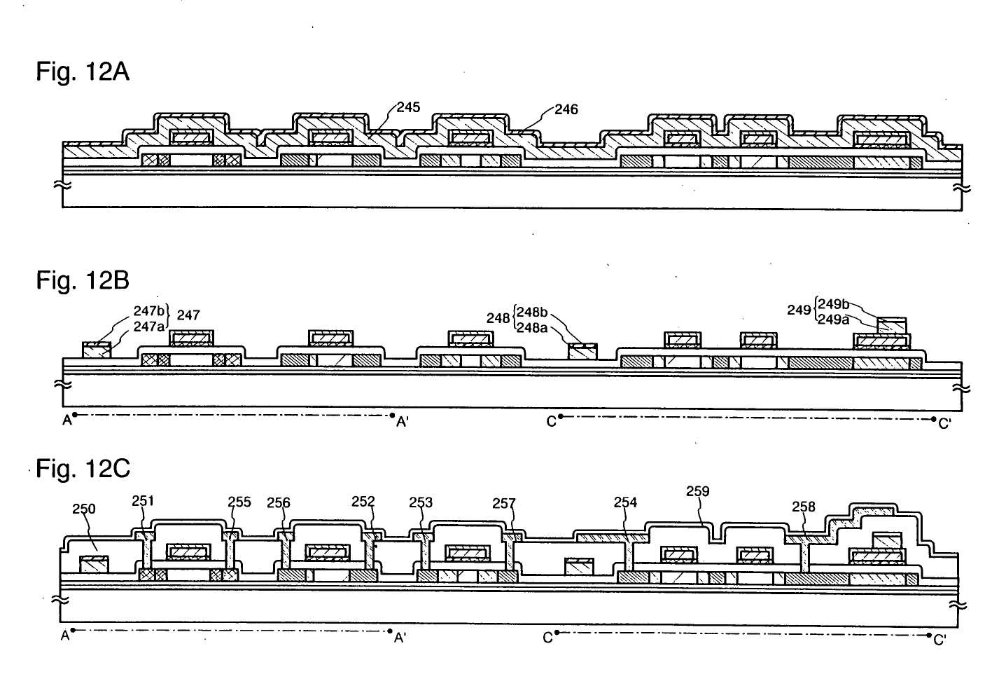

After the activation and hydrogenation steps are completed, a second conductive layer is formed as a gate wiring. The second conductive layer is formed of a conductive layer (D) made from a low resistance material which has aluminum (Al) or copper (Cu) as its principal constituent. Whichever is used, the resistivity of the second conductive layer is set to between 0.1 and 10 μΩcm. It is appropriate that, a conductive layer (E) made from titanium (Ti), tantalum (Ta), tungsten (W), or molybdenum (Mo) is laminated with the conductive layer (D). In this embodiment, an aluminum (Al) film containing between 0.1 and 2% by weight of titanium (Ti) is formed as conductive layer (D) 245, and a titanium (Ti) film is formed as a conductive layer (E) 246. The conductive layer (D) 245 may be formed with a thickness of 200 to 400 nm (preferably 250 to 350 nm), and the conductive layer (E) may be formed with a thickness of 50 to 200 nm (preferably 100 to 150 nm). (FIG. 12A)

The conductive layer (E) 246 and the conductive layer (D) 245 are then etched in order to form a gate wiring connected to the gate electrode, forming gate wirings 247 and 248 and a capacitor wiring 249. In the etching process, dry etching using a mixed gas of SiCl₄, Cl₂ and BCl₃ is performed first, removing a volume from the surface of the conductive layer (E) to the middle of the conductive layer (D). By then removing the conductive layer (D) by wet etching using a phosphoric acid-based etching solution, the gate wiring can be formed while maintaining the selective processibility with the base film.

FIGS. 14B and 15B show top views of this state, and the cross sections taken along the line A-A′ and the line C-C′ correspond to the A-A′ and C-C′ cross sections, respectively, in FIG. 12B. Further, the cross sections taken along the line B-B′ and the line D-D′ correspond to the B-B′ and D-D′, respectively, in FIG. 16B and in FIG. 17B. In FIGS. 14B and 15B, a portion of gate wirings 247 and 248 overlap, and are in electrical contact with, a portion of the gate electrodes 228, 229, and 231. This state is also made clear from the cross-sectional structure views of FIG. 16B and FIG. 17B corresponding to the cross sections taken along the lines B-B′ and D-D′, and the conductive layer (C) forming the first conductive layer is electrically connected with the conductive layer (D) forming the second conductive layer.

A first interlayer insulating film 250 is deposited with a thickness of 500 to 1500 nm from a hydrogenated silicon oxynitride film manufactured in accordance with the # 1883 or the #1884 conditions shown in Table 1, forming the interlayer insulating film 120. An hydrogenated silicon oxynitride film with a thickness of 1000 nm is formed here by introducing SiH₄ into the reaction chamber at 8.4 Pa·1/sec, N₂O at 203 Pa·1/sec, and H₂ at 844 Pa·1/sec, setting the reaction pressure to 40 Pa, the substrate temperature to 400° C., and the electric discharge power density to 0.4 W/cm². Next, contact holes reaching the source regions and the drain regions are formed in the island-like semiconductor layers to form source wirings 251 to 254, and drain wirings 255 to 258. Although not shown in the figures, a three layer structure electrode of a 100 nm Ti film, a 300 nm Al film containing Ti, and a 150 nm film formed successively by sputtering is used as the electrodes in embodiment 4.

Next, a silicon nitride film, a silicon oxide film, or a silicon oxynitride film is formed with a thickness of between 50 and 500 nm (typically from 100 to 300 nm) as a passivation film 259. Whichever film is used, it is formed so as to become a dense film, providing isolation from external moisture, and further, has the added function of acting as a cap layer in a second hydrogenation step, performed later. For example, the passivation film 259 is formed of a dense silicon nitride film with a thickness of 200 nm, and if hydrogenation processing is performed in this state, then a desirable result can be obtained with respect to improving the TFT characteristics. This may be performed for between 1 and 12 hours at 300 to 500° C. in an atmosphere of 3 to 100% hydrogen, or in a nitrogen atmosphere. If heat treatment is performed in this temperature range, then the hydrogen contained in the hydrogenated silicon oxynitride films forming the first interlayer insulating film 250 and the gate insulating film 220 is released. However, the diffusion of hydrogen is prevented on the upper side by its being capped by the dense silicon nitride film, and therefore the released hydrogen preferentially diffuses to the lower layer side. Hydrogenation then proceeds with the diffusion of hydrogen from the first interlayer insulating film 250 to the gate insulating film 220 underneath, and from the gate insulating film 220 to the island-like semiconductor layers 204, and 210 to 212. Hydrogen is similarly released from the hydrogenated silicon oxynitride film used for the base film 202, and therefore the island-like semiconductor layers 204, and 210 to 212 are hydrogenated from both the lower and upper sides. Of course, in addition to this method, a similar result can also be obtained by performing the hydrogenation process before the above silicon nitride film is deposited, or by using plasma hydrogenation. Additionally, plasma hydrogenation may be used together with the above hydrogenation method. Note that openings may be formed in the passivation film 259 in locations at which contact holes, for connecting a pixel electrode and a drain wiring, will later be formed. (FIG. 12C)

FIGS. 14C and 15C show top views of this state, and the cross sections taken along the line A-A′ and the line C-C′ correspond to the A-A′ and C-C′, respectively, in FIG. 12C. Further, the cross sections taken along the line B-B′ and the line D-D′ correspond to the B-B′ and D-D′, respectively, in FIG. 16C and in FIG. 17C. In FIGS. 14C and 15C, the first interlayer insulating film is omitted, and the source wirings 251, 252, and 254, and the drain wirings 255, 256, and 258, are connected to source and drain regions of the island-like semiconductor layers 204, 205, and 207, respectively, which are not shown in the figures, through contact holes formed in the first interlayer insulating film.

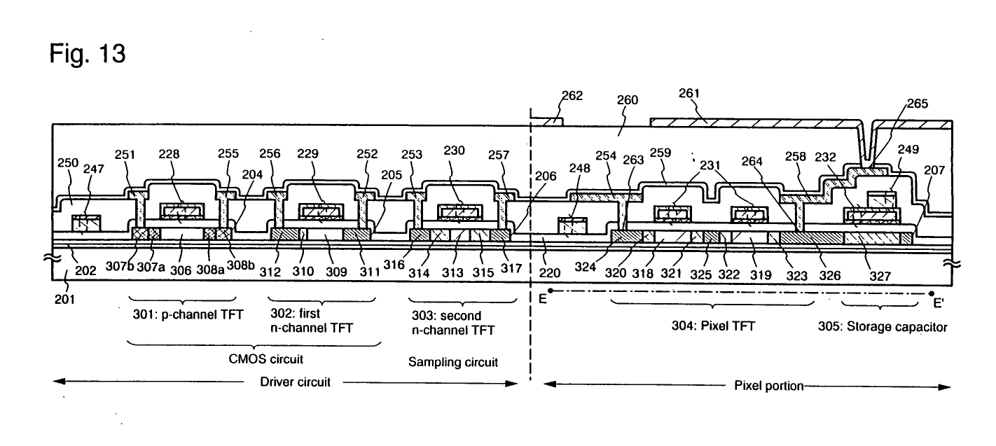

A second interlayer insulating film 260 is formed next from an organic resin with a thickness of 1.0 to 1.5 μm. Materials such as polyimide, acrylic, polyamide, polyimide amide, and BCB (benzocyclobutene) can be used as the organic resin. A thermal polymerization type polyimide is used here, and this is burnt at 300° C. after application to the substrate. A contact hole reaching the drain wiring 258 is then formed in the second interlayer insulating film 260 to form pixel electrodes 261 and 262. A transparent conductive film is used for the pixel electrodes in a transmitting type liquid crystal display device, and a metallic film is used in a reflecting type liquid crystal display device. A transmitting type liquid crystal display device is aimed in this embodiment, and therefore a 100 nm thick indium tin oxide (ITO) film is formed by sputtering. (FIG. 13)

The substrate having the TFTs of the driver circuit and the pixel TFT of the pixel portion on the same substrate is thus completed. A p-channel TFT 301, a first n-channel TFT 302, and a second n-channel TFT 303 are formed in the driver circuit, and a pixel TFT 304 and a storage capacitor 305 are formed in the pixel portion. For convenience, this type of substrate is referred to as an active matrix substrate throughout this specification.

The p-channel TFT 301 of the driver circuit has a channel forming region 306, source regions 307a and 307b, and drain regions 308a and 308b in the island-like semiconductor layer 204. The first n-channel TFT 302 has a channel forming region 309, an LDD region (Lov) 310 overlapping the gate electrode 229, a source region 311, and a drain region 312 in the island-like semiconductor layer 205. The length of the Lov region in the channel length direction is from 0.5 to 3.0 μm, preferable between 1.0 and 1.5 μm. A channel forming region 313, an Lov region, and an Loff region (LDD regions 314 and 315 which does not overlap the gate electrode, hereafter referred to as an Loff region) are formed in the island-like semiconductor layer 206 of the second n-channel TFT 303, and the length of the Loff region in the channel length direction is from 0.3 to 2.0 μm, preferably between 0.5 and 1.5 μm. The LDD region 314 is between channel forming region 313 and source region 316, and the LDD region 315 is between channel forming region 313 and drain region 317. The island-like semiconductor layer 207 of the pixel TFT 304 has channel forming regions 318 and 319, Loff regions 320 to 323, and source or drain regions 324 to 326. The length of the Loff region in the channel length direction is from 0.5 to 3.0 μm, preferably between 1.5 and 2.5 μm. In addition, the storage capacitor 305 is formed from the capacitor wirings 232 and 249, an insulating film made from the same material as the gate insulating film, and a semiconductor layer 327 connected to the drain region 326 of the pixel TFT 304 and having an added impurity element that imparts n-type conductivity. In FIG. 13 a double gate structure is used for the pixel TFT 304, but a single gate structure may be used, and a multi-gate structure in which a plural number of gate electrodes are formed may also be used without hindrance.

Thus, as above, the present invention is characterized in that a hydrogenated silicon oxynitride film manufactured using a gas mixture of SiH₄, N₂O, and H₂ is used for insulating films such as a base film, a gate insulating film, and an interlayer insulating film which forms a TFT. With the hydrogenated silicon oxynitride film, the defect level density, such as neutral defects and electric charge defects, is low, and further, the interface level density is low in the interface with the semiconductor layers. As a result, characteristics of the TFT manufactured is as follows: the S value can be made from 0.10 to 0.30 V/dec, Vₜₕ can be made from 0.5 to 2.5 V, and the electric field effect mobility can be made from 120 to 250 cm²/V·sec in the n-channel TFT. Further, in the p-channel TFT, the S value can be made from 0.10 to 0.30 V/dec, Vₜₕ can be made from −2.5 to −0.5 V, and the electric field effect mobility can be made from 80 to 150 cm²/V·sec. This results in the driver voltage being reduced, and the power consumption being reduced. A high quality display device can be realized by using this type of active matrix substrate.

### Embodiment 5

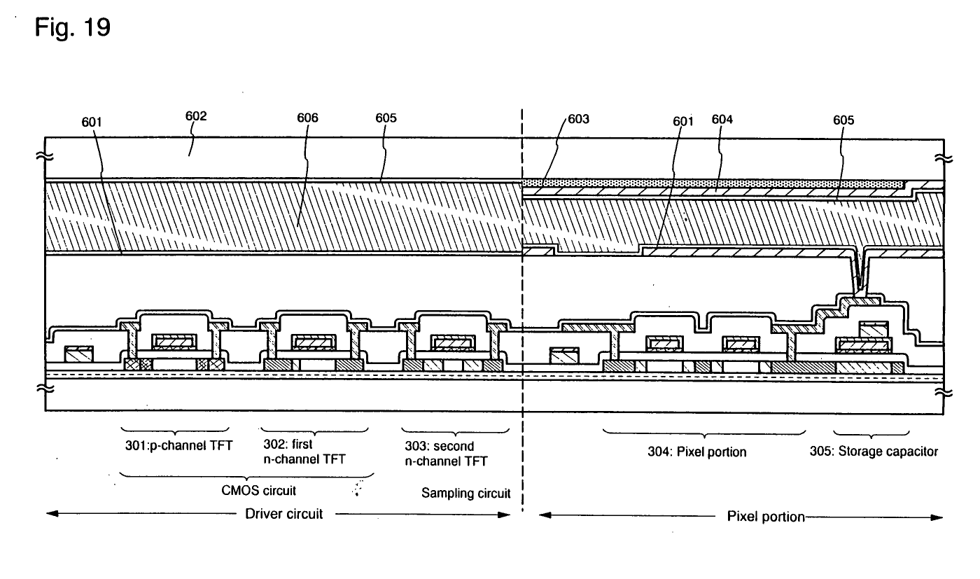

In this embodiment, a process of manufacturing an active matrix type liquid crystal display device from the active matrix substrate of embodiment 4 is explained. As shown in FIG. 19, an alignment film 601 is formed on the active matrix substrate in the state of FIG. 13. A polyimide resin is often used for the alignment film of a liquid crystal display device. A light shielding film 603, a transparent conductive film 604, and an alignment film 605 are formed on an opposing substrate 602, which is opposed to the active matrix substrate. After forming the alignment films, a rubbing process is performed so that the liquid crystal molecules are oriented with a certain fixed pre-tilt angle. The active matrix substrate, on which the pixel portion and the CMOS circuit are formed, and the opposing substrate are then joined together by a sealing material or spacers (both not shown in the figures) in accordance with a known cell construction process. Next, a liquid crystal material 606 is injected between both substrates, and the cell is completely sealed by an end-sealing material (not shown in the figures). A known liquid crystal material may be used as the liquid crystal material. Thus the active matrix type liquid crystal display device shown in FIG. 19 is completed.

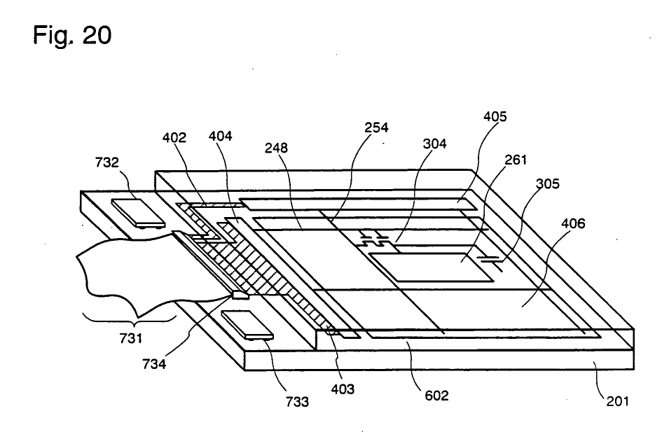

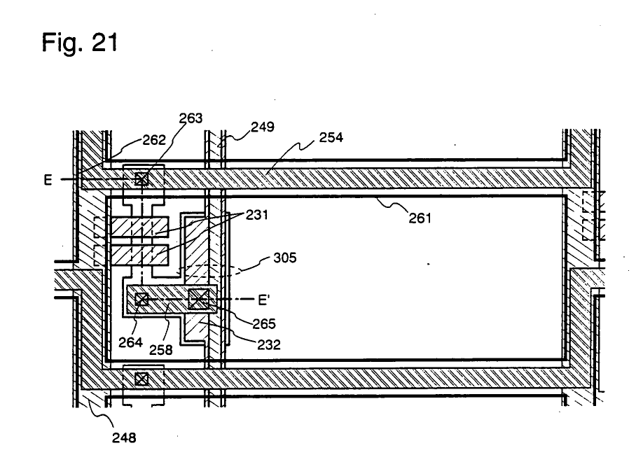

Next, the structure of the active matrix type liquid crystal display device is explained using the perspective view of FIG. 20 and the top view of FIG. 21. Note that FIG. 20 and FIG. 21 correspond to the cross-sectional structure views of FIGS. 9A to 13 and FIG. 19 and therefore common symbols are used. Further, the cross-sectional structure taken along the line E-E′ shown in FIG. 21 corresponds to the cross-sectional view of the pixel matrix circuit shown in FIG. 13.

In FIG. 20, the active matrix substrate is composed of a pixel portion 406, a scanning signal driver circuit 404, and an image signal driver circuit 405 formed on the glass substrate 201. The pixel TFT 304 is formed in the display region, and the driver circuit formed in the periphery thereof is structured based on a CMOS circuit. The scanning signal driver circuit 404 and the image signal driver circuit 405 are connected to the pixel TFT 304 by the gate wiring 248 and the source wiring 254, respectively. Further, an FPC (flexible print circuit) 731 is connected to an external input terminal 734, and input wirings 402 and 403 are connected to the respective driver circuits. Reference numerals 732 and 733 denote IC chips.

FIG. 21 is a top view showing nearly one full pixel of the display region 406. The gate wiring 248 intersects, through a gate insulating film not shown in the figure, with the semiconductor layer 212 underneath. A source region, a drain region, and an Loff region made from an n⁻ region, are formed in the semiconductor layer, although not shown in the figure. Further, reference numeral 263 denotes a contact area of the source wiring 254 and the source region 324 (not shown), reference numeral 264 denotes a contact area of the drain wiring 258 and the drain region 326 (not shown), and reference numeral 265 denotes a contact area of the drain wiring 258 and the pixel electrode 261. The storage capacitor 305 is formed of the region in which the semiconductor layer 327 extending from the drain region 326 of the pixel TFT 304 overlaps the capacitor wirings 232 and 249 through the gate insulating film.

Note that the active matrix type liquid crystal display device of Embodiment 5 is explained with reference to the structure explained in embodiment 4, but the structure is not limited to that of embodiment 4; an active matrix substrate fabricated by applying the structure shown in Embodiment 3 may be used. Whichever is used, provided that it is an active matrix substrate completed by TFTs using insulating films formed from the hydrogenated silicon oxynitride film of the present invention, the operator may suitably set the design parameters, such as TFT structure and circuit arrangement.

### Embodiment 6

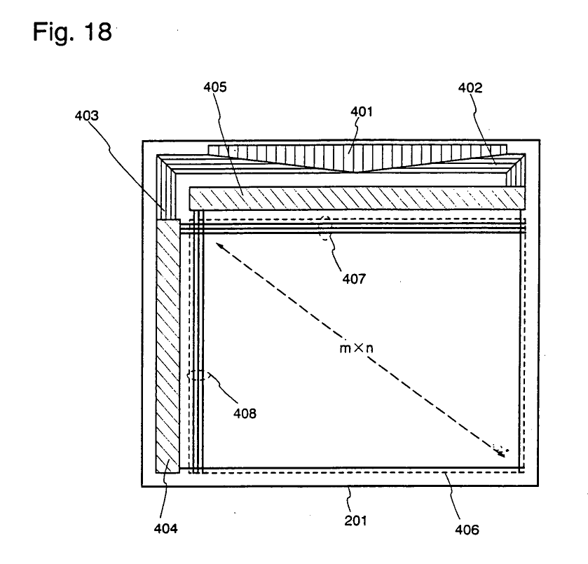

FIG. 18 is a view showing an example of the arrangement of input-output terminals, a display region, and driver circuits of a liquid crystal display device. There are m gate wirings and n source wirings that intersect in a matrix manner in the pixel portion 406. For example, 480 gate wirings 407 and 640 source wirings 408 are formed when the pixel density is VGA (Video Graphics Array), and 768 gate wirings 407 and 1024 source wirings 408 are formed for the case of XGA (eXtended Graphics Array). The screen size of the display region becomes 340 mm for a 13-inch class in diagonal length, and becomes 460 mm for an 18-inch class in diagonal. It is necessary to form the gate wirings from low resistance materials as shown in Embodiment 3 in order to realize this kind of liquid crystal display device. If the time constant (resistance×capacitance) of the gate wirings becomes large, then the response speed of the scanning signal becomes slow, and the liquid crystal cannot be driven at high speed. For example, when the material forming the gate wiring has a resistivity of 100 μΩcm, then a 6 inch class screen size is the closest to the limit, but if the resistivity is 3 μΩcm, then a screen size up to a 27 inch class is in a manageable range.

The scanning signal driver circuit 404 and the image signal driver circuit 405 are formed in the periphery of the display region 406. The length of the gate wirings of these driver circuits necessarily becomes longer with increasing screen size of the display region, and therefore it is preferable to form the gate wirings from a low resistance material such as aluminum (Al) or copper (Cu), as shown in embodiment 4, in order to realize a large screen. Further, with the present invention, the input wirings 402 and 403 which connect the input terminal 401 with each driver circuit can be formed of the same material as the gate wirings, and this can contribute to making the wiring resistance lower.

On the other hand, for cases in which the screen size of the display region is in the 2-inch class, the length of the diagonal becomes on the order of 45 mm, and if a TFT is manufactured, the device can be fit within 50×50 mm², including the driver circuits formed in the periphery. In this case, it is not always necessary to form the gate wirings with a low resistance material such as that shown in embodiment 4, and it is possible to form the gate wirings with the same material used to form the gate electrodes, such as Ta or W.

A liquid crystal display device with this kind of constitution can be completed using the active matrix substrate completed in embodiment 4. Furthermore, it can be implemented by applying the constitution shown in Embodiment 3 to Embodiment 4. The layout of the circuit arrangement shown here is an example, and the scanning signal driver circuit 404 may be formed on both sides of the display region 406. In any case, provided that it is an active matrix substrate completed with TFTs using insulating films formed from the hydrogenated silicon oxynitride film of the present invention, the operator may suitably set the design parameters, such as TFT structure and circuit arrangement.

### Embodiment 7

Examples of using a crystalline semiconductor film, which is an amorphous semiconductor film crystallized by laser annealing or thermal annealing, as an active layer of a TFT are shown in Embodiments 1 to 4. However, it is possible to apply the hydrogenated silicon oxynitride film of the present invention to a base film, and a gate insulating film or an interlayer insulating film, by substituting an amorphous semiconductor film, typically an amorphous silicon film, for the crystalline semiconductor as the active layer.

### Embodiment 8

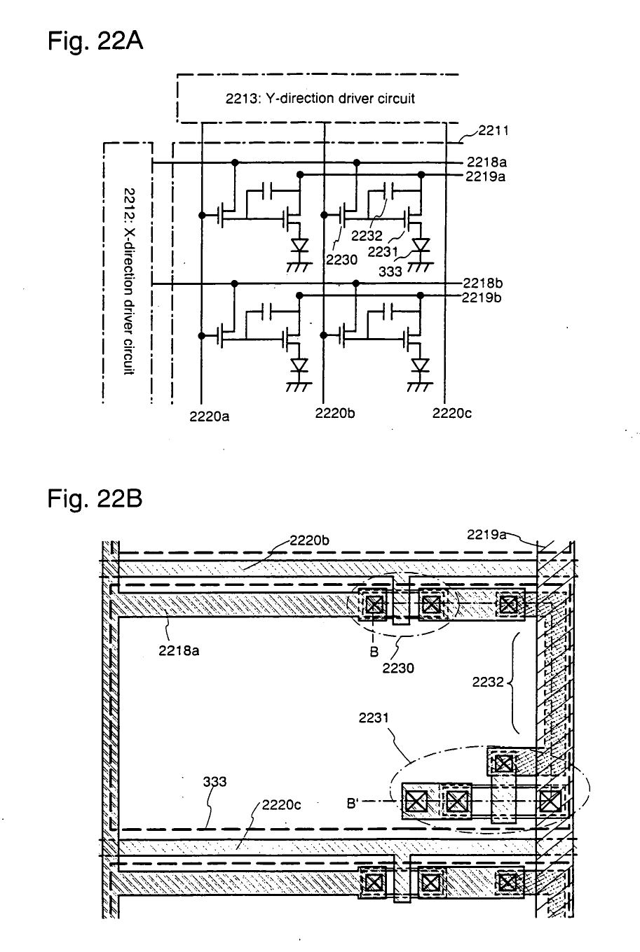

An example of the present invention being applied to a display device using an active matrix organic electroluminescence (organic EL) material (organic EL display device) is explained with reference to FIGS. 22A and 22B. FIG. 22A shows a circuit diagram of an active matrix type organic EL display device in which a display region and a driver circuit in the periphery, are formed on a glass substrate. The organic EL display device is comprised of a display region 2211, an x-direction peripheral driver circuit 2212 and a y-direction peripheral driver circuit 2213 formed on the substrate. The display region 2211 is composed of a switching TFT 2230, a storage capacitor 2232, a current control TFT 2231, an organic EL element 333, x-direction signal lines 2218a and 2218b, power supply lines 2219a and 2219b, y-direction signal lines 2220a, 2220b, and 2220c, etc.

FIG. 22B shows a top view of nearly one full pixel. The switching TFT 2230 is formed similarly to the p-channel TFT 301 shown in FIG. 13, and the current control TFT 2231 is formed similarly to the n-channel TFT 303 shown in FIG. 13.

For an organic EL display device with an operation mode in which light is emitted toward the top of the TFT, a reflective electrode such as Al is used to form a pixel electrode. The constitution of a pixel region of the organic EL display device is shown here, but the present invention may be applied to an active matrix type display device with integrated peripheral circuits in which, similar to Embodiment 1, driver circuits are formed in the periphery of the pixel region. Although not shown in the figure, it is also possible to make a color display by providing the display with color filters. Provided that it is an active matrix substrate in which the base layer shown in Embodiment 1 is formed, the active matrix type organic EL display device, in which the above forms are freely combined, can be manufactured.

### Embodiment 9

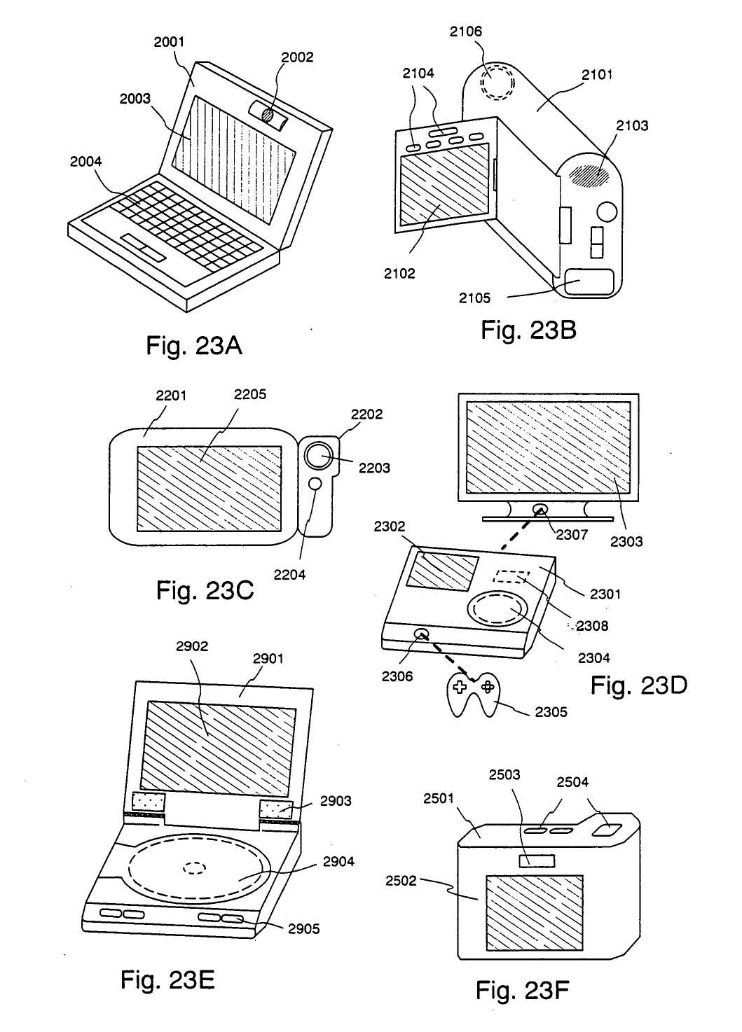

An active matrix substrate, a liquid crystal display device and an EL type display device manufactured by implementing the present invention can be used in various electro-optical devices. The present invention can then be applied to all electronic equipment that incorporates this kind of electro-optical device as a display medium. The following can be given as this type of electronic equipment: a personal computer; a digital camera; a video camera; a portable information terminal (such as a mobile computer, a portable telephone, and an electronic book); and a navigation system. Some examples of these are shown in FIGS. 23A to 23F.

FIG. 23A shows a personal computer, which is composed of a main body 2001 comprising a microprocessor and a memory, an image input unit 2002, a display device 2003, and a keyboard 2004. The liquid crystal display device and the organic EL display device of the present invention can be applied to the display device 2003.

FIG. 23B shows a video camera, which is composed of a main body 2101, a display device 2102, an audio input unit 2103, operation switches 2104, a battery 2105, and an image receiving unit 2106. The liquid crystal display device and the organic EL display device of the present invention can be applied to the display device 2102.

FIG. 23C shows a portable information terminal, which is composed of a main body 2201, an image input unit 2202, an image receiving unit 2203, operation switches 2204, and a display device 2205. The liquid crystal display device and the organic EL display device of the present invention can be applied to the display device 2205.

FIG. 23D shows electronic game equipment such as a television game or a video game, which is composed of: a main body 2301 loaded with electronic circuits 2308 such as a CPU, and a recording medium 2304; a controller 2305; a display device 2303; and a display device 2302 built into the main body 2301. The display device 2303 and the display device 2302 incorporated into the main body 2301 may both display the same information, or the former may be taken as a main display and the latter may be taken as a sub-display to display information from the recording medium 2304 or the equipment operation status, or touch sensors can be added to use it as an operating panel. Further, in order for the main body 2301, the controller 2305, and the display device 2303 to transmit signals to each other, wired communication may be used, or sensor units 2306 and 2307 can be provided for either wireless communication or optical communication. The liquid crystal display device and the organic EL display device of the present invention can be applied to the display devices 2302 and 2303. A conventional CRT can also be used for the display device 2303.

FIG. 23E shows a player which uses a recording medium with a program recorded therein (hereafter referred to as a recording medium), and which is composed of a main body 2901, a display device 2902, a speaker unit 2903, a recording medium 2904, and operation switches 2905. Note that a DVD (Digital Versatile Disk), or Compact Disk (CD) is used as a recording medium for this device, and that the device is capable of reproduction of a music program, display of an image, and information display through video games (or television games) and through the Internet. The liquid crystal display device and the organic EL display device of the present invention can be suitably used for the display device 2402.

FIG. 23F shows a digital camera, which is composed of a main body 2501, a display device 2502, an eye piece portion 2503, operation switches 2504, and an image receiving unit (not shown in the figure). The liquid crystal display device and the organic EL display device of the present invention can be applied to the liquid display device 2502.

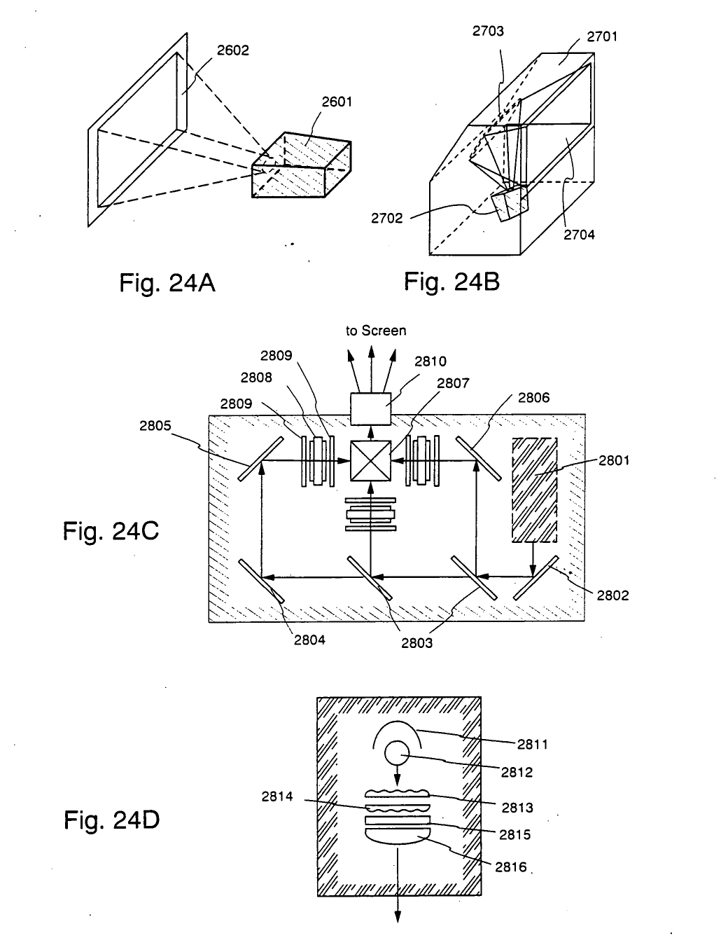

FIG. 24A shows a front type projector, which is composed of an optical light source system and display device 2601, and a screen 2602. The present invention can be applied to the display device, and to other signal control circuits. FIG. 24B shows a rear type projector, which is composed of a main body 2701, an optical light source system and display device 2702, a mirror 2703, and a screen 2704. The present invention can be applied to the display device, and to other signal control circuits.

FIG. 24C is a drawing showing an example of the structure of the optical light source system and the display devices 2601 and 2702 in FIGS. 24A and 24B. The optical light source system and display devices 2601 and 2702 each consist of an optical light source system 2801, mirrors 2802 and 2804 to 2806, a dichroic mirror 2803, a beam splitter 2807, liquid crystal display devices 2808, a phase difference plate 2809, and an optical projection system 2810. The optical projection system 2810 is composed of a plural number of optical lenses. In FIG. 24C an example three plate system is shown in which three liquid crystal display devices 2808 are used, but there are no special limitations and an optical system of single plate system is acceptable, for example. Further, the operator may suitably set optical systems such as optical lenses, polarizing film, film to regulate the phase, IR films, within the optical path shown by the arrows in FIG. 24C. In addition, FIG. 24D shows an example of the structure of the optical light source system 2801 of FIG. 24C. In this embodiment, the optical light source system 2801 is composed of a reflector 2811, a light source 2812, lens arrays 2813 and 2814, a polarizing conversion element 2815, and a condenser lens 2816. Note that the optical light source system shown in FIG. 24D is an example, and it is not limited to the structure shown in the figure.

Further, although not shown in the figures, it is possible to apply the present invention to a read-in circuit of a navigation system or an image sensor. Thus the application range for the present invention is extremely wide, and it can be applied to electronic equipment in all fields. Further, the electronic equipment of this embodiment can be realized with a composition that uses any combination of embodiments 1 to 6.

### Embodiment 10

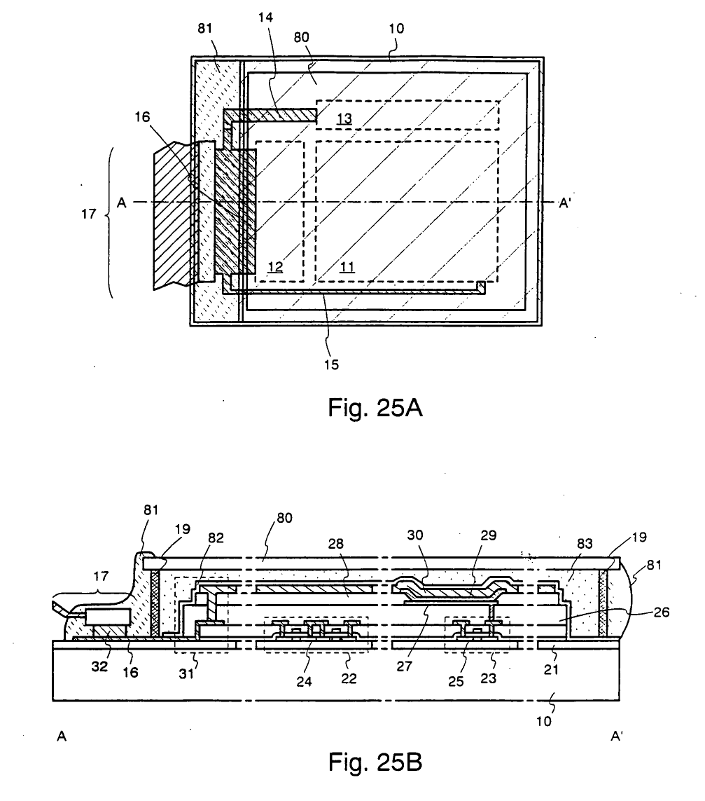

An explanation is given in this embodiment on an example of manufacturing, from an active matrix substrate, a self-light emitting type display panel (hereafter referred to as an EL display device) using an electroluminescence (EL) material. FIG. 25A is a top view of such an EL display panel. In FIG. 25A reference numeral 10 denotes a substrate, 11 denotes a pixel portion, 12 denotes a source side driver circuit, and 13 denotes a gate side driver circuit. The respective driver circuits are led to an FPC 17 through wirings 14 to 16, and thus connected to external equipment.

A cross-sectional view corresponding to the cross section taken along the line A-A′ of FIG. 25A is shown in FIG. 25B. An opposing plate 80 is provided over at least the pixel portion, and preferably above the driver circuits and the pixel portion, at this point. The opposing plate 80 is joined to the active matrix substrate, on which the TFTs and a self-light emitting layer using the EL material is formed, by a sealing material 19. A filler (not shown in the figures) is mixed into the sealing material 19, and the two substrates can be joined together with a nearly uniform spacing by the filler. In addition, the structure is sealed up by an end-sealing material 81 on the outside of the sealing material 19, and on the top and periphery of the FPC 17. Materials such as a silicon resin, an epoxy resin, a phenol resin, or a butyl rubber are used for the end-sealing material 81.

If the active matrix substrate 10 and the opposing substrate 80 are thus joined, a space is formed between the substrates. A filler 83 fills the space. The filler 83 also has the effect of an adhesive for bonding the opposing plate 80. Materials such as PVC (polyvinyl chloride), epoxy resin, silicone resin, PVB (polyvinyl butyral), and EVA (ethylene vinyl acetate) can be used as the filler 83. Further, the self-light emitting layer is weak with regard to moisture and easily deteriorates, and therefore a drying agent such as barium oxide desirably is mixed in the filler 83, then a moisture absorption effect can be maintained. In addition, a passivation film 82 is formed from a silicon nitride film or a silicon oxynitride film on the self-light emitting layer, making a structure to prevent corrosion due to alkaline elements contained in the filler 83.

Materials such as a glass plate, an aluminum plate, a stainless steel plate, an FRP (fiberglass-reinforced plastics) plate, a PVF (polyvinyl fluoride) film, a Mylar film (a trademark of Du pont Corp.), a polyester film, and an acrylic film can be used as the opposing plate 80. Further, the moisture resistance can be improved by using a sheet with a structure in which several tens of μm of aluminum foil is sandwiched between PVF films or between Mylar films. The EL element is thus in an airtight state, and is closed off from the atmosphere.

Furthermore, a driver circuit TFT (Note that a CMOS circuit combining an n-channel TFT and a p-channel TFT is shown in the figures here) 22 and a pixel TFT 23 (however, only a TFT for controlling the current to the EL element is shown in the figures here) are formed on a base film 21 on the substrate 10 in FIG. 25B. Of these TFTs, the n-channel TFT, in particular, is provided with an LDD region in order to prevent a reduction in the on current due to the hot carrier effect, and to prevent a drop in the characteristics due to a shift in Vth, or bias stress.

For example, the p-channel TFT 301 and the n-channel TFT 302 shown in FIG. 13 may be used as the driver circuit TFT 22. Further, although depending upon the drive voltage, the first n-channel TFT 204 shown in FIGS. 5A to 5E, or a p-channel TFT having a similar structure, may be used for the pixel TFT provided that the drive voltage is 10 V or more. The first n-channel TFT 202 has a structure in which an LDD region is formed overlapping the gate electrode on the drain side, but if the drive voltage is 10 V or less. deterioration due to the hot carrier effect can mostly be ignored, and therefore the LDD region need not be formed.

In manufacturing an EL display device from an active matrix substrate in the state of FIG. 13, an interlayer insulating film (planarizing film) 26 is formed from a resin material on the source wiring and on the drain wiring, and a pixel electrode 27 electrically connected to the drain of the pixel TFT 23 is formed from a transparent conductive film. An indium oxide and tin oxide compound (referred to as ITO), or an indium oxide and zinc oxide compound can be used as the transparent conductive film. After forming the pixel electrode 27, an insulating film 28 is then formed to form an opening on the pixel electrode 27.

Next, a self-light emitting layer is formed. Any known EL materials (a hole injection layer, a hole transport layer, a light emitting layer, an electron transport layer, or an electron injection layer) may be freely combined and used in a laminate structure or a single layer structure for the self-light emitting layer 29. Further, there are low molecular weight materials and high molecular weight materials (polymers) as EL materials. An evaporation method is used for low molecular weight materials, but it is possible to use a simple method such as spin coating, printing, or inkjet method for high molecular weight materials.

The self-light emitting layer may be formed by a method such as evaporation method, an ink jet method, or a dispenser method, using a shadow mask. Whichever method is used, by forming a light emitting layer that can emit light of different wavelengths for each pixel (red light emitting layer, green light emitting layer, and blue light emitting layer), a color display becomes possible. In addition, a method of combining color changing layers (CCM) with color filters, and a method of combining white light emitting layers with color filters exist, and either method may also be used. Of course, a single color light EL display device is also possible.

A cathode 30 is then formed on the self-light emitting layer 29. It is preferable to remove as much as possible of the moisture and oxygen existing in the interface between the cathode 30 and the self-light emitting layer 29. Therefore, it is necessary to form the self-light emitting layer 29 and the cathode 30 successively inside a vacuum, or to form the self-light emitting layer 29 in an inert atmosphere and then form the cathode 30 in vacuum without exposure to the air. It is possible to perform the above film deposition in this embodiment by using a multi-chamber system (cluster tool system) deposition device.

Note that a laminate structure of a LiF (lithium fluoride) film and an Al (aluminum) film is used for the cathode 30 in this embodiment. Specifically, a 1-nm thick LiF (lithium fluoride) film is formed on the self-light emitting layer 29 by evaporation, and a 300-nm thick aluminum film is formed thereon. Of course, an MgAg electrode, a known cathode material, may also be used. The cathode 30 is then connected to the wiring 16 in the region denoted by reference numeral 31. The wiring 16 is a power supply line for applying a predetermined voltage to the cathode 30, and is connected to the FPC 17 through an anisotropic conductive paste material 32. Additionally, a resin layer 80 is formed on the FPC 17, increasing the adhesive strength of this area.

In order to electrically connect the cathode 30 and the wiring 16 in the region denoted by reference numeral 31, it is necessary to form contact holes in the interlayer insulating film 26 and the insulating film 28. The contact holes may be formed during etching of the interlayer insulating film 26 (when forming the pixel electrode contact hole), and during etching of the insulating film 28 (when forming the opening before forming the self-light emitting layer). Further, etching may proceed in one shot all the way to the interlayer insulating film 26 when etching the insulating film 28. In this case, the contact holes can be given a good shape provided that the interlayer insulating film 26 and the insulating film 28 are the same resin material.

In addition, the wiring 16 is electrically connected to the FPC 17 through the gap (filled by the end-sealing material 81) between the sealing material 19 and the substrate 10. Note that an explanation of the wiring 16 has been made here, and that the wirings 14 and 15 are also connected electrically to the FPC 17 by similarly passing underneath the sealing material 19.

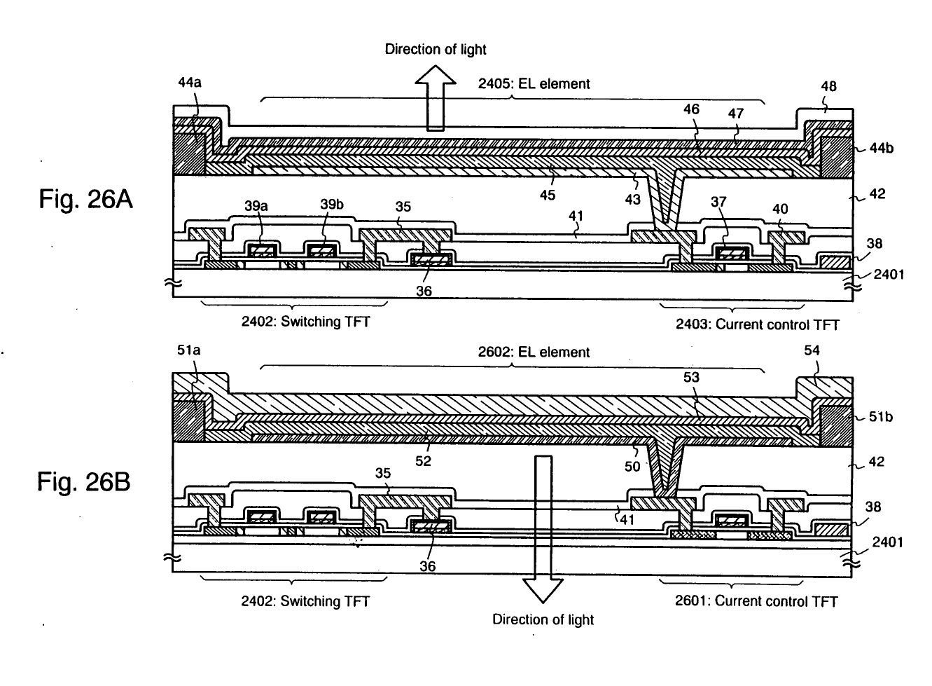

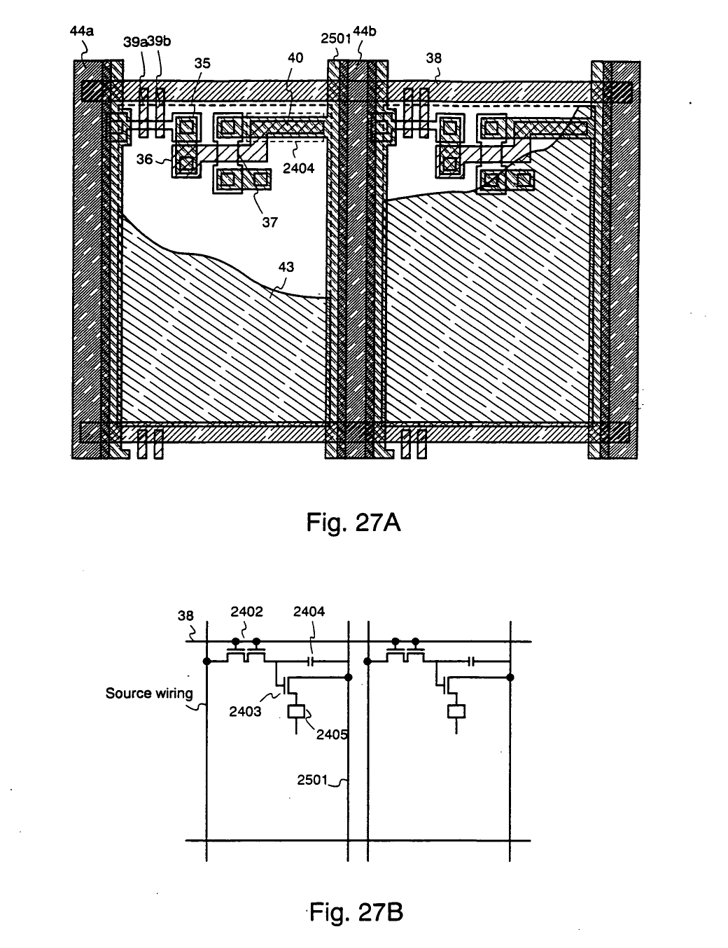

A more detailed cross-sectional structure of a pixel portion is shown now in FIGS. 26A and 26B, a top surface structure thereof is shown in FIG. 27A, and a circuit view is shown in FIG. 27B. In FIG. 26A, a switching TFT 2402 formed on a substrate 2401 is formed with the same structure as that of the pixel TFT 304 in FIG. 13. By using a double gate structure, in essence the structure is two TFTs in series, and this has the advantage that the off current value can be lowered by forming an LDD. Note that although this embodiment employs a double gate structure, a single gate structure may also be used, as may a triple gate structure and a multi-gate structure having a larger number of gates.

Further, a current control TFT 2403 is formed using the first n-channel TFT 302 shown in FIG. 13. This TFT structure is a structure in which the LDD region is formed overlapping the gate electrode only on the drain side, and with which the parasitic capacitance between the gate and the drain is reduced, as well as the series resistance, to thereby improve the current drive performance. From other perspectives as well, the fact that this structure is used possesses an extremely important meaning. A current control TFT is an element for controlling the amount of current flowing in an EL element, and there is much current flow, so it is an element in which there is a great danger of degradation due to heat or due to hot carriers. Therefore, by forming the LDD region partially overlapping the gate electrode in the current control TFT, deterioration of the TFT can be prevented, and stability of operation can be improved. A drain wiring 35 of the switching TFT 2402 is electrically connected to a gate electrode 37 of the current control TFT by a wiring 36. Further, a wiring denoted by reference numeral 38 is a gate wiring for electrically connecting gate electrodes 39a and 39b of the switching TFT 2402.

A single gate structure is shown in the figures for the current control TFT 2403 in this embodiment, but a multi-gate structure, with a plural number of TFTs connected in series, may also be used. In addition, a structure for performing heat radiation with high efficiency, in which a plural number of TFTs are connected in parallel, in essence dividing the channel forming region into a plural number of channel forming regions, may also be used. This type of structure is an effective countermeasure against heat degradation.

The wiring which becomes the gate electrode 37 of the current control TFT 2403 is the region shown by reference numeral 2404, and overlaps a drain wiring 40 of the current control TFT 2403, through an insulating film, as shown in FIG. 27A. At this point a capacitor is formed in the region shown by reference numeral 2404. The capacitor 2404 functions as a capacitor for retaining the voltage applied to the gate of the current control TFT 2403. Note that the drain wiring 40 is connected to a current supply line (power supply line) 2501, and a fixed voltage is constantly applied thereto.

A first passivation film 41 is formed on the switching TFT 2402 and the current control TFT 2403, and a planarizing film 42 is formed thereon from an insulating resin film. It is very important to level the level difference due to the TFTs by using the planarizing film 42. The self-light emitting layer formed later is extremely thin, so that there are cases where the level difference causes the luminescence to be defective. Therefore, to form the self-light emitting layer with as level a surface as possible, it is preferable to perform flattening before forming the pixel electrode.

Reference numeral 43 denotes a pixel electrode (cathode of the EL element) formed of a conductive film with high reflectivity, and the electrode is electrically connected to the drain of the current control TFT 2403. It is preferable to use a low resistance conductive film, such as an aluminum alloy film, a copper alloy film, and a silver alloy film, or a laminate film of such films, as the pixel electrode 43. A laminate structure with other conductive films may also be used, of course. Further, a light emitting layer 45 is formed in a groove (corresponding to the pixel) between banks 44a and 44b formed of insulating films (preferably resins). Note that only one pixel is shown in the figures here, but the light emitting layer may be divided to correspond to each of the colors R (red), G (green), and B (blue). A [symbol] conjugate polymer-based material is used as an organic EL material for the light emitting layer. Polyparaphenylene vinylenes (PPVs), polyvinyl carbazoles (PVCs), and polyfluorenes can be given as typical polymer-based materials. Note that there are several types of PPV-based organic EL materials, and the materials described in Shenk. H., Becker, H., Gelsen, O., Kluge, E., Kreuder, W., and Spreitzer, H., “Polymers for Light Emitting Diodes”, Euro Display, Proceedings, 1999, pp. 33-7, and in Japanese Patent Application Laid-open No. Hei 10-92576, for example, may be used.

As specific light emitting layers, cyano-polyphenylene vinylene may be used as a red light radiating light emitting layer, polyphenylene vinylene may be used as a green light radiating light emitting layer, and polyphenylene vinylene or polyalkylphenylene may be used as a blue light radiating light emitting layer. The film thickness may be between 30 and 150 nm (desirably between 40 and 100 nm). However, the above example is merely an example of the organic EL materials that can be used as light emitting layers, and it is not necessary to limit the organic EL materials to these. The self-light emitting layer (a layer for luminescence and for performing carrier motion for luminescence) may be formed by freely combining light emitting layers, charge transport layers, and charge injection layers. For example, this embodiment shows an example using polymer-based materials as light emitting layers, but low molecular weight organic EL materials may also be used. Further, it is possible to use inorganic materials such as silicon carbide, as charge transport layers and charge injection layers. Known materials can be used for these organic EL materials and inorganic materials.

A laminate structure EL layer, in which a hole injection layer 46 from PEDOT (polythiophene) or PAni (polyaniline) is formed on the light emitting layer 44, is used for the self-light emitting layer in this embodiment. An anode 47 is then formed on the hole injection layer 46 made from a transparent conductive film. The light generated by the light emitting layer 44 is radiated toward the upper surface (toward the top of the TFT) in this embodiment, so the anode must be transparent to light. An indium oxide and tin oxide compound, or an indium oxide and zinc oxide compound can be used for the transparent conductive film. However, because it is formed after formation of the low heat resistance light emitting layer and the hole injection layer, it is preferable to use a material which can be formed at as low a temperature as possible.

At the point where the anode 47 is formed, a self-light emitting element 2405 is complete. Note that what is referred to as the EL element 2405 here indicates the capacitor formed of the pixel electrode (cathode) 43, the light emitting layer 44, the hole injection layer 46, and the anode 47. As shown in FIG. 27A, the pixel electrode 43 nearly matches the area of the pixel, so the entire pixel functions as an EL element. Therefore, the luminescence usage efficiency is very high, and a bright image display is possible.

An additional second passivation film 48 is then formed on the anode 47 in this embodiment. It is preferable to use a silicon nitride film or a silicon oxynitride film as the second passivation film 48. The purpose of this is the isolation of the EL element from the outside, and it has meaning of preventing degradation due to the oxidation of the organic EL material, and controlling degas from the organic EL material. Thus the reliability of the EL display device can be improved.

Thus the EL display panel of the present invention has a pixel portion consists of pixels structured as in FIGS. 27A and 27B, has a switching TFT with sufficiently low off current value, and has a current control TFT strong against hot carrier injection. Therefore, an EL display panel which has high reliability, and in which good image display is possible, is obtained.

An example of inverting the structure of the self-light emitting layer is shown in FIG. 26B. A current control TFT 2601 is formed with the same structure as that of the p-channel TFT 301 in FIG. 13. Embodiment 1 may be referred to for the manufacturing process. A transparent conductive film is used as a pixel electrode (anode) 50 in this embodiment. Specifically, a conductive film comprised of a compound of indium oxide and zinc oxide is used. Of course, a conductive film comprised of a compound of indium oxide and tin oxide may also be used.

After then forming banks 51a and 51b from insulating films, a light emitting layer 52 is formed from polyvinyl carbazole by solution coating. An electron injection layer 53 is formed on the light emitting layer 52 from potassium acetylacetonate (expressed as acacK), and a cathode 54 is formed thereon from an aluminum alloy. In this case the cathode 54 also functions as a passivation film. An EL element 2602 is thus formed. The light generated by the light emitting layer 52 is radiated toward the substrate on which the TFT is formed in this embodiment, as shown by the arrows. It is preferable to use a p-channel TFT for the current control TFT 2601 in cases when a structure like that of this embodiment is used.

An EL display device such as that shown in this embodiment can be used as the display portion of the electronic equipment of Embodiment 9.

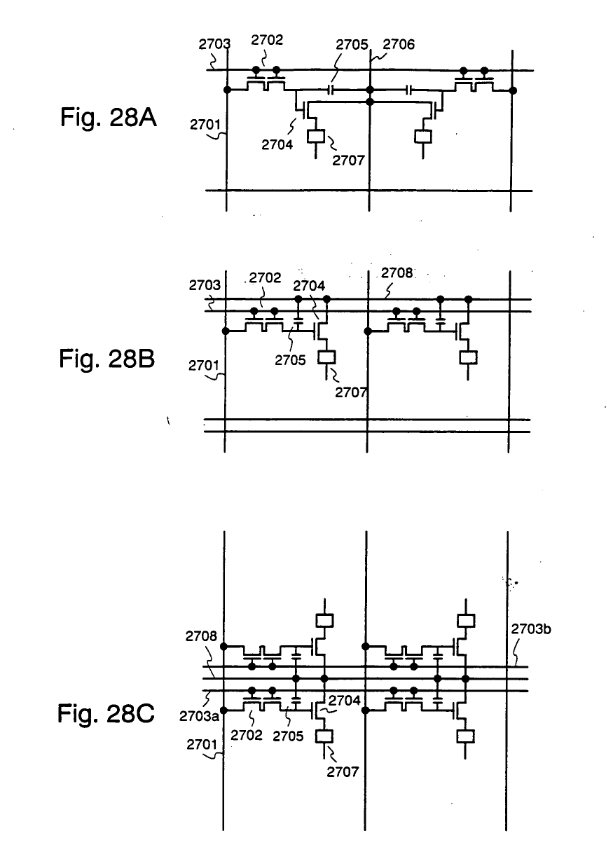

Examples of cases in which the pixel structure differs from that of the circuit diagram illustrated in FIG. 27B are shown in FIGS. 28A to 28C. Note that in this embodiment, reference numeral 2701 denotes a source wiring of a switching TFT 2702, reference numeral 2703 denotes a gate wiring of the switching TFT 2702, reference numeral 2704 denotes a current control TFT, 2705 denotes a capacitor, 2706 and 2708 denote electric current supply lines, and 2707 denotes an EL element.

FIG. 28A is an example of a case in which the electric current supply line 2706 is common between two pixels. Namely, this is characterized in that the two pixels are formed having linear symmetry around the electric current supply line 2706. In this case the number of electric current supply lines can be reduced, and therefore the pixel portion can be made even more high definition.

Further, FIG. 28B is an example of a case in which the electric current supply line 2708 is formed parallel to the gate wiring 2703. Note that in FIG. 28B, the structure is formed such that the electric current supply line 2708 and the gate wiring 2703 do not overlap, but, provided that both are wirings formed on different layers, they can be formed to overlap through an insulating film. In this case, the exclusive surface area can be shared by the electric current supply line 2708 and the gate wiring 2703, and therefore the pixel portion can be made even more high definition.

Furthermore, FIG. 28C is characterized in that the electric current supply line 2708 and the gate wirings 2703 are formed in parallel, similar to the structure of FIG. 28B, and additionally, in that the two pixels are formed so as to have linear symmetry around the electric current supply line 2708. In addition, it is effective to form the electric current supply line 2708 so as to overlap with one of the gate wirings 2703. In this case, the number of electric current supply lines can be reduced, and therefore the pixel portion can be made even more high definition. In FIGS. 28A and 28B, the capacitor 2404 is formed in order to store the voltage applied to the gate of the current control TFT 2403, but it is also possible to omit the capacitor 2404.

Using the n-channel TFT of the present invention, such as that shown in FIG. 26A, as the current control TFT 2403, there is an LDD region formed so as to overlap the gate electrode through the gate insulating film. A so-called parasitic capacitance is formed in the region where the LDD region overlaps the electrode, but this embodiment is characterized by the active use of this parasitic capacitance as a substitute for the capacitor 2404. The capacitance of the parasitic capacitance changes by the surface area in which the gate electrode and the LDD region overlap, and therefore is determined by the length of the LDD region contained in the overlapping region. Further, it is also possible to omit the capacitor 2705 in the structures of FIGS. 28A, 28B, and 28C.

Note that the circuit structure of the EL display device shown in this embodiment may be formed by selecting the TFT structure shown in Embodiment 1, and forming the circuit shown in FIGS. 28A to 28C. Furthermore, it is possible to use the EL display panel of this embodiment as the display portion of the electronic equipment of Embodiment 9.

By applying the hydrogenated silicon oxynitride film of the present invention, manufactured by plasma CVD with SiH₄, N₂O, and H₂ as raw material gasses, to a semiconductor device, typically a TFT, and using it for a gate insulating film, a base film, and a protective insulating film or an interlayer insulating film, a TFT can be manufactured in which there are no shifts in Vₜₕ and which is stable with respect to BTS stress. Furthermore, by using this type of insulating film it is possible to manufacture the TFT on a glass substrate and to realize a higher quality semiconductor device, typically a liquid crystal display device or an organic EL display device.

1-40. (Canceled).

41. A semiconductor device comprising a pixel portion and a driver circuit on a substrate, comprising:
a base film formed on said substrate;
a first, second, and third semiconductor layers over said base film;
a first gate electrode adjacent to said first semiconductor layer with a gate insulating film interposed therebetween, wherein a first LDD region in said first semiconductor layer is not overlapped with said first gate electrode;
a second gate electrode adjacent to said second semiconductor layer with said gate insulating film interposed therebetween, a second LDD region in said second semiconductor layer is overlapped with said second gate electrode;
a third gate electrode adjacent to said third semiconductor layer with said gate insulating film interposed therebetween, a third LDD region in said third semiconductor layer is partly overlapped with said third gate electrode,
wherein said pixel portion comprises said first semiconductor film, and said driver circuit comprises said second and third semiconductor films, and
wherein said gate insulating film comprises a hydrogenated silicon oxynitride film having an oxygen concentration from 55 to 70 atomic %, a nitrogen concentration from 0.1 to 6 atomic %, and a hydrogen concentration from 0.1 to 3 atomic %.

42. The semiconductor device according to claim 41, wherein said semiconductor device is one selected from the group consisting of a personal computer, a video camera, a portable information terminal, a digital camera, a digital video disk player, an electronic game equipment, and a projector.

43. The semiconductor device according to claim 41, wherein said semiconductor device is an electroluminescence display device.

44. The semiconductor device according to claim 41, wherein said substrate is a glass substrate.

45. A semiconductor device comprising a pixel portion and a driver circuit on a substrate, comprising:
a first, second, and third semiconductor layers over said substrate;
a first gate electrode adjacent to said first semiconductor layer with a gate insulating film interposed therebetween, wherein a first LDD region in said first semiconductor layer is not overlapped with said first gate electrode;
a second gate electrode adjacent to said second semiconductor layer with said gate insulating film interposed therebetween, a second LDD region in said second semiconductor layer is overlapped with said second gate electrode;
wherein said pixel portion comprises said first semiconductor film, and said driver circuit comprises said second and third semiconductor films, and
wherein said gate insulating film comprises a hydrogenated silicon oxynitride film having an oxygen concentration from 55 to 70 atomic %, a nitrogen concentration from 0.1 to 6 atomic %, and a hydrogen concentration from 0.1 to 3 atomic %.

46. The semiconductor device according to claim 45, wherein said semiconductor device is one selected from the group consisting of a personal computer, a video camera, a portable information terminal, a digital camera, a digital video disk player, an electronic game equipment, and a projector.

47. The semiconductor device according to claim 45, wherein said semiconductor device is an electroluminescence display device.

48. A semiconductor device comprising a pixel portion and a driver circuit on a substrate, comprising:
a first, second, and third semiconductor layers over said substrate;
a first gate electrode adjacent to said first semiconductor layer with a gate insulating film interposed therebetween, wherein a first LDD region in said first semiconductor layer is not overlapped with said first gate electrode;
a second gate electrode adjacent to said second semiconductor layer with said gate insulating film interposed therebetween, a second LDD region in said second semiconductor layer is overlapped with said second gate electrode;
wherein said pixel portion comprises said first semiconductor film, and said driver circuit comprises said second and third semiconductor films,
wherein said gate insulating film comprises a hydrogenated silicon oxynitride film having an oxygen concentration from 55 to 70 atomic %, a nitrogen concentration from 0.1 to 6 atomic %, and a hydrogen concentration from 0.1 to 3 atomic %, and
wherein said gate insulating film has a thickness between 40 and 150 nm.

49. The semiconductor device according to claim 48, wherein said semiconductor device is one selected from the group consisting of a personal computer, a video camera, a portable information terminal, a digital camera, a digital video disk player, an electronic game equipment, and a projector.

50. The semiconductor device according to claim 48, wherein said semiconductor device is an electroluminescence display device.

51. A semiconductor device comprising a pixel portion and a driver circuit on a substrate, comprising:
a first, second, and third semiconductor layers over said substrate;
a first gate electrode over said first semiconductor layer with a gate insulating film interposed therebetween, wherein a first LDD region in said first semiconductor layer is not overlapped with said first gate electrode;
a second gate electrode over said second semiconductor layer with said gate insulating film interposed therebetween, a second LDD region in said second semiconductor layer is overlapped with said second gate electrode;
wherein said pixel portion comprises said first semiconductor film, and said driver circuit comprises said second and third semiconductor films, and
wherein said gate insulating film comprises a hydrogenated silicon oxynitride film having an oxygen concentration from 55 to 70 atomic %, a nitrogen concentration from 0.1 to 6 atomic %, and a hydrogen concentration from 0.1 to 3 atomic %.

52. The semiconductor device according to claim 51, wherein said semiconductor device is one selected from the group consisting of a personal computer, a video camera, a portable information terminal, a digital camera, a digital video disk player, an electronic game equipment, and a projector.

53. The semiconductor device according to claim 51, wherein said semiconductor device is an electroluminescence display device.

54. A semiconductor device comprising a pixel portion and a driver circuit on a substrate, comprising:
a first, second, and third semiconductor layers over said substrate;
a first gate electrode over said first semiconductor layer with a gate insulating film interposed therebetween, wherein a first LDD region in said first semiconductor layer is not overlapped with said first gate electrode;
a second gate electrode over said second semiconductor layer with said gate insulating film interposed therebetween, a second LDD region in said second semiconductor layer is overlapped with said second gate electrode;
wherein said pixel portion comprises said first semiconductor film, and said driver circuit comprises said second and third semiconductor films,
wherein said gate insulating film comprises a hydrogenated silicon oxynitride film having an oxygen concentration from 55 to 70 atomic %, a nitrogen concentration from 0.1 to 6 atomic %, and a hydrogen concentration from 0.1 to 3 atomic %, and
wherein said gate insulating film has a thickness between 40 and 150 nm.

55. The semiconductor device according to claim 54, wherein said semiconductor device is one selected from the group consisting of a personal computer, a video camera, a portable information terminal, a digital camera, a digital video disk player, an electronic game equipment, and a projector.

56. The semiconductor device according to claim 54, wherein said semiconductor device is an electroluminescence display device.

57. The semiconductor device according to claim 41, wherein said second semiconductor layer comprises a second source region, a second drain region, and a second channel region between said second source and drain regions, said second LDD region is between said second channel and drain regions, and said second source region is in contact with said second channel region.

58. The semiconductor device according to claim 45, wherein said second semiconductor layer comprises a second source region, a second drain region, and a second channel region between said second source and drain regions, said second LDD region is between said second channel and drain regions, and said second source region is in contact with said second channel region.

59. The semiconductor device according to claim 48, wherein said second semiconductor layer comprises a second source region, a second drain region, and a second channel region between said second source and drain regions, said second LDD region is between said second channel and drain regions, and said second source region is in contact with said second channel region.

60. The semiconductor device according to claim 51, wherein said second semiconductor layer comprises a second source region, a second drain region, and a second channel region between said second source and drain regions, said second LDD region is between said second channel and drain regions, and said second source region is in contact with said second channel region.

61. The semiconductor device according to claim 54, wherein said second semiconductor layer comprises a second source region, a second drain region, and a second channel region between said second source and drain regions, said second LDD region is between said second channel and drain regions, and said second source region is in contact with said second channel region.

62. The semiconductor device according to claim 41, wherein said semiconductor device further comprising:
a first insulating film over said first, second, and third gate electrodes;
a second insulating film over said first insulating film;
a third insulating film comprising organic resin over said second insulating film;
a pixel electrode over said third insulating film, said pixel electrode electrically connected to said first semiconductor layer.

63. The semiconductor device according to claim 45, wherein said semiconductor device further comprising:
a first insulating film over said first and second gate electrodes;
a second insulating film over said first insulating film;
a third insulating film comprising organic resin over said second insulating film;
a pixel electrode over said third insulating film, said pixel electrode electrically connected to said first semiconductor layer.

64. The semiconductor device according to claim 48, wherein said semiconductor device further comprising:
a first insulating film over said first and second gate electrodes;
a second insulating film over said first insulating film;
a third insulating film comprising organic resin over said second insulating film;
a pixel electrode over said third insulating film, said pixel electrode electrically connected to said first semiconductor layer.

65. The semiconductor device according to claim 51, wherein said semiconductor device further comprising:
a first insulating film over said first and second gate electrodes;
a second insulating film over said first insulating film;
a third insulating film comprising organic resin over said second insulating film;
a pixel electrode over said third insulating film, said pixel electrode electrically connected to said first semiconductor layer.

66. The semiconductor device according to claim 54, wherein said semiconductor device further comprising:
a first insulating film over said first and second gate electrodes;
a second insulating film over said first insulating film;
a third insulating film comprising organic resin over said second insulating film;
a pixel electrode over said third insulating film, said pixel electrode electrically connected to said first semiconductor layer.
